(19) United States
(12) Patent Application Publication
(10) Pub. No.: US 2025/0318408 A1
(43) Pub. Date: Oct. 9, 2025

(54) DISPLAY DEVICE AND METHOD FOR MANUFACTURING THE SAME

(71) Applicant: Samsung Display Co., LTD., Yongin-si (KR)

(72) Inventors: JUNYOUNG LEE, Yongin-si (KR); JUNWOO YOU, Yongin-si (KR); JEONGWEON SEO, Yongin-si (KR)

(21) Appl. No.: 19/037,492

(22) Filed: Jan. 27, 2025

(30) Foreign Application Priority Data
Apr. 8, 2024 (KR) 10-2024-0047068

(51) Int. Cl. H10K 59/80; H10K 59/12

(52) U.S. Cl. CPC H10K 59/873; H10K 59/1201

(57) ABSTRACT

An electronic device includes a lower coating layer, which includes a base resin and a plurality of carbon fillers dispersed in the base resin, and a display panel disposed on the lower coating layer. The plurality of carbon fillers includes a plurality of first sub-carbon fillers disposed in a first arrangement direction and a plurality of second sub-carbon fillers disposed in a second arrangement direction crossing the first arrangement direction. A lower surface of the lower coating layer includes a convex portion convex in a direction away from the display panel and be spaced apart from the display panel with an upper surface of the lower coating layer interposed therebetween.

This application claims priority to Korean Patent Application No. 10-2024-0047068, filed on Apr. 8, 2024, and all the benefits accruing therefrom under 35 U.S.C. § 119, the content of which in its entirety is herein incorporated by reference.

### BACKGROUND

### 1. Field

The disclosure herein relates to a display device including carbon fillers and a method for manufacturing the same.

### 2. Description of the Related Art

Various display devices such as televisions, mobile phones, tablet computers, and game consoles are being developed. The display devices may be composed of various members such as a display panel and an input sensing layer and may include a plurality of functional layers (e.g., a heat dissipation layer, a shielding layer, and the like) to maintain reliability. The plurality of functional layers increases a thickness of a display device, and research is underway to improve the thickness.

### SUMMARY

The disclosure provides a display device that has a reduced thickness and exhibits excellent reliability.

The disclosure also provides a method for manufacturing a display device, the method having excellent manufacturing efficiency.

An embodiment of the inventive concept provides an electronic device including a lower coating layer including a base resin and a plurality of carbon fillers dispersed in the base resin; and a display panel disposed on the lower coating layer. The plurality of carbon fillers includes a plurality of first sub-carbon fillers disposed in a first arrangement direction and a plurality of second sub-carbon fillers disposed in a second arrangement direction crossing the first arrangement direction; and a lower surface of the lower coating layer includes a convex portion convex in a direction away from the display panel and is spaced apart from the display panel with an upper surface of the lower coating layer interposed therebetween.

In an embodiment, each of the plurality of carbon fillers may be a carbon fiber.

In an embodiment, the lower coating layer may further include a first coating layer including the base resin and the plurality of first sub-carbon fillers dispersed in the base resin; and a second coating layer including the base resin and the plurality of second sub-carbon fillers dispersed in the base resin and disposed between the first coating layer and the display panel.

In an embodiment, the lower surface of the lower coating layer may be the lower surface of the first coating layer.

In an embodiment, the lower surface of the lower coating layer may further include a flat portion adjacent to the convex portion, and the plurality of first sub-carbon fillers may be disposed in the convex portion and may not be disposed in the flat portion.

In an embodiment, the plurality of carbon fillers may further include: a plurality of third sub-carbon fillers disposed in the first arrangement direction; and a plurality of fourth sub-carbon fillers disposed in the second arrangement direction, and the lower coating layer may further include: a third coating layer including the base resin and the plurality of third sub-carbon fillers dispersed in the base resin and disposed between the second coating layer and the display panel; and a fourth coating layer including the base resin and the plurality of fourth sub-carbon fillers dispersed in the base resin and disposed between the third coating layer and the display panel.

In an embodiment, each of the plurality of carbon fillers may have a rod shape, and a length of a long side of the rod shape may be about 10 micrometers (μm) to about 200 μm.

In an embodiment, the base resin may be a photocurable resin.

In an embodiment, the base resin may include at least one of an epoxy-based resin, an acrylic-based resin, a urethane-based resin, or a silicone-based resin.

In an embodiment, based on a total weight (100 wt %) of the lower coating layer, a weight of the plurality of carbon fillers may be about 50 wt % to about 90 wt %.

In an embodiment, the upper surface of the lower coating layer may be flat.

In an embodiment of the inventive concept, a method for manufacturing a display device includes preparing a display panel; and providing a lower coating layer including a base resin and a plurality of carbon fillers dispersed in the base resin on a surface of the display panel. The plurality of carbon fillers include a plurality of first sub-carbon fillers disposed in a first arrangement direction and a plurality of second sub-carbon fillers disposed in a second arrangement direction crossing the first arrangement direction, and the providing the lower coating layer includes: providing a second coating composition including a preliminary base resin and a plurality of preliminary second sub-carbon fillers dispersed in the preliminary base resin in a first direction to form a preliminary second coating layer; curing the preliminary second coating layer to form a second coating layer including the base resin and the plurality of second sub-carbon fillers dispersed in the base resin; on a surface of the second coating layer, providing a first coating composition including the preliminary base resin and a plurality of preliminary first sub-carbon fillers dispersed in the preliminary base resin in a second direction crossing the first direction to form a preliminary first coating layer; and curing the preliminary first coating layer to form a first coating layer including the base resin and the plurality of first sub-carbon fillers dispersed in the base resin.

In an embodiment, the plurality of carbon fillers may further include a plurality of third sub-carbon fillers disposed in the first arrangement direction and a plurality of fourth sub-carbon fillers disposed in the second arrangement direction, and the forming the lower coating layer may further include: prior to the forming the preliminary second coating layer, providing a fourth coating composition including the preliminary base resin and a plurality of preliminary fourth sub-carbon fillers dispersed in the preliminary base resin on the surface of the display panel in the second direction to form a preliminary fourth coating layer; curing the preliminary fourth coating layer to form a fourth coating layer including the base resin and the plurality of fourth sub-carbon fillers dispersed in the base resin; on a surface of the fourth coating layer, providing a third coating composition including the preliminary base resin and a plurality of preliminary third sub-carbon fillers dispersed in the preliminary base resin in the first direction to form a preliminary third coating layer; and curing the preliminary third coating layer to form a third coating layer including the base resin and the plurality of third sub-carbon fillers dispersed in the base resin.

In an embodiment, the first coating composition and the second coating composition may be provided by a dispensing method.

In an embodiment, each of the plurality of carbon fillers may be a carbon fiber.

In an embodiment, each of the plurality of carbon fillers may have a rod shape, and a length of the long side of the rod may be about 10 μm to about 200 μm.

In an embodiment, a thickness of each of the preliminary first coating layer and the preliminary second coating layer may be about 5 μm to about 30 μm.

In an embodiment, based on a total weight of the first coating composition, a weight of the plurality of preliminary first sub-carbon fillers may be about 50 wt % to about 90 wt %, and based on a total weight of the second coating composition, a weight of the plurality of preliminary second sub-carbon fillers may be about 50 wt % to about 90 wt %.

In an embodiment, ultraviolet light may be provided in the curing the preliminary first coating layer and the curing the preliminary second coating layer.

In an embodiment, the preliminary base resin may include at least one of an epoxy-based resin, an acrylic-based resin, a urethane-based resin, or a silicone-based resin.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept.

In the drawings:

FIG. 1 is a perspective view illustrating an embodiment of a display device according to the inventive concept;

FIG. 2 is an exploded perspective view illustrating an embodiment of the display device according to the inventive concept;

FIG. 3A is a cross-sectional view illustrating a portion corresponding to line I-I′ of FIG. 2;

FIG. 3B is a cross-sectional view illustrating an embodiment of a portion of the display device according to the inventive concept;

FIG. 4 is a cross-sectional view illustrating an embodiment of a portion of the display device according to the inventive concept;

FIG. 5 is an exploded perspective view illustrating an embodiment of a portion of the display device according to the inventive concept;

FIG. 6 is a cross-sectional view illustrating an embodiment of a portion of the display device according to the inventive concept;

FIG. 7 is a cross-sectional view illustrating an embodiment of a portion of the display device according to the inventive concept;

FIG. 8 is a plan view illustrating a portion corresponding to region AA′ of FIG. 2;

FIG. 9 is an exploded perspective view illustrating an embodiment of a portion of the display device according to the inventive concept;

FIG. 10 is a cross-sectional view illustrating an embodiment of a portion of the display device according to the inventive concept;

FIG. 11 is a cross-sectional view illustrating an embodiment of a portion of the display device according to the inventive concept;

FIG. 12A is a flowchart showing an embodiment of a method of manufacturing a display device according to the inventive concept;

FIG. 12B is a flowchart showing an embodiment of the method of manufacturing the display device according to the inventive concept;

FIG. 13 schematically illustrates an embodiment of a step of manufacturing the display device according to the inventive concept;

FIG. 14 schematically illustrates an embodiment of a step of manufacturing the display device according to the inventive concept;

FIG. 15 schematically illustrates an embodiment of a step of manufacturing the display device according to the inventive concept;

FIG. 16 schematically illustrates an embodiment of a step of manufacturing the display device according to the inventive concept;

FIG. 17 schematically illustrates an embodiment of a step of manufacturing the display device according to the inventive concept;

FIG. 18A schematically illustrates an embodiment of a step of manufacturing the display device according to the inventive concept; and

FIG. 18B schematically illustrates an embodiment of a step of manufacturing the display device according to the inventive concept.

### DETAILED DESCRIPTION

In the invention, various modifications may be made, various forms may be used, and illustrative embodiments will be illustrated in the drawings and described in detail in the text. However, this is not intended to limit the present invention to a specific form disclosed, and it will be understood that all changes, equivalents, or substitutes which fall in the spirit and technical scope of the invention should be included.

In this specification, it will be understood that when an element (or region, layer, portion, etc.) is referred to as being “on”, “connected to” or “coupled to” another element, it may be directly on, connected or coupled to the other element, or intervening elements may be present.

Like reference numerals refer to like elements throughout. In addition, in the drawings, the thicknesses, ratios, and dimensions of elements are exaggerated for effective description of the technical contents. As used herein, the term “and/or” includes any and all combinations that the associated configurations may define.

It will be understood that, although the terms first, second, etc. may be used herein to describe various elements, these elements should not be limited by these terms. These terms are only used to distinguish one element from another element. For example, a first element could be termed a second element without departing from the scope of the invention. Similarly, the second element may also be referred to as the first element. The terms of a singular form include plural forms unless otherwise specified.

In addition, terms, such as “below”, “lower”, “above”, “upper” and the like, are used herein for ease of description to describe one element's relation to another element(s) as illustrated in the drawing figures. The above terms are relative concepts and are described based on the directions indicated in the drawings.

It will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

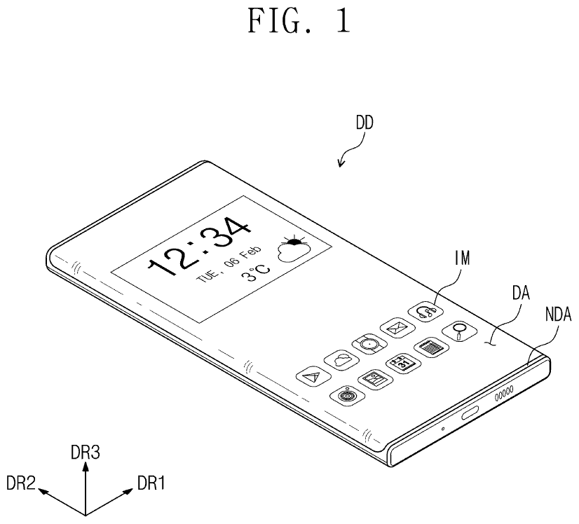

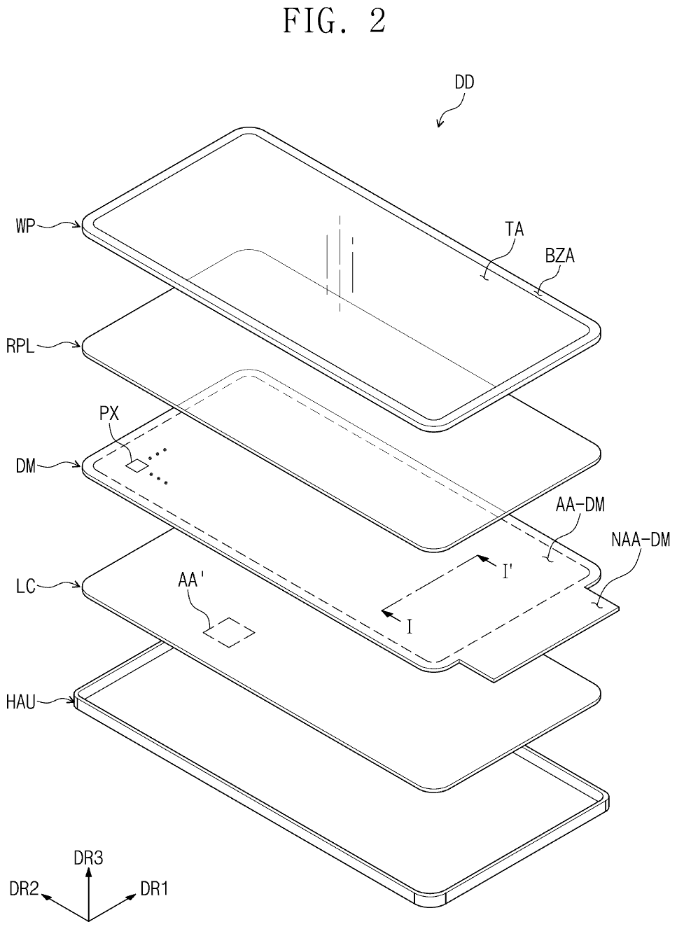

Hereinafter, a display device in an embodiment of the inventive concept will be described with reference to the accompanying drawings. FIG. 1 is a perspective view illustrating an embodiment of a display device according to the inventive concept. FIG. 2 is an exploded perspective view illustrating an embodiment of the display device according to the inventive concept.

The display device DD in an embodiment of the inventive concept illustrated in FIG. 1 may be activated according to an electrical signal. In an embodiment, the display device DD may be a personal computer, a laptop computer, a personal digital terminal, a game console, a portable electronic device, a television, a monitor, an external billboard, a car navigation system, or a wearable device, for example, but the embodiment of the inventive concept is not limited thereto. In FIG. 1, the display device DD is illustrated as a mobile phone. In this specification, an electronic device may be the display device DD or may include the display device DD.

The display device DD in an embodiment of the inventive concept may display an image IM through a display region DA. The display region DA may include a plane defined by a first direction axis DR1 and a second direction axis DR2. The display region DA may include a curved surface bent from at least one side of the plane defined by the first direction axis DR1 and the second direction axis DR2. The display device DD in an embodiment of the inventive concept, which is illustrated in FIG. 1, is illustrated to include two curved surfaces bent from opposite sides of the plane defined by the first direction axis DR1 and the second direction axis DR2. However, the shape of the display region DA is not limited thereto. In an embodiment, the display region DA may include only a flat surface defined by the first direction axis DR1 and the second direction axis DR2, and the display region DA may further include four curved surfaces respectively bent from at least two side surfaces, e.g., four side surfaces of the plane defined by the first direction axis DR1 and the second direction axis DR2, for example.

The display device DD in an embodiment of the inventive concept may be flexible. Being “flexible” refers to a bendable characteristic, and the display device may include all structures from a completely foldable structure to a structure that may be bent to the level of several nanometers. In an embodiment, the display device DD may be a foldable display device. In addition, the display device DD may be rigid, for example.

A non-display region NDA may be adjacent to the display region DA. In the disclosure, the term “adjacent” may mean “next to” (e.g., “immediately next to”), but is not limited thereto. The non-display region NDA may surround the display region DA. Accordingly, the shape of the display region DA may be substantially defined by the non-display region NDA. However, this is illustrated in an embodiment, and the non-display region NDA may be adjacent to only one side of the display region DA or may be omitted. The display region DA may be provided in various shapes and is not limited to a particular embodiment.

FIG. 1 and following drawings illustrate the first direction axis DR1 to third direction axis DR3, and directions indicated by the first to third direction axes DR1, DR2, and DR3 described in this specification are relative concepts and may be converted into other directions. In addition, the directions indicated by the first to third direction axes DR1, DR2, and DR3 may be described as first to third directions, and the same reference numerals may be used for them. In this specification, the first direction axis DR1 and the second direction axis DR2 may be orthogonal to each other, and the third direction axis DR3 may be a normal direction with respect to a plane defined by the first direction axis DR1 and the second direction axis DR2.

The thickness direction of the display device DD may be parallel to the third direction axis DR3 which is the normal direction with respect to the plane defined by the first and second directions axes DR1 and DR2. In this specification, the upper surface (or front surface, upper portion surface, upper side) and lower surface (or rear surface, lower portion surface, lower side) of members constituting the display device DD may be defined based on the third direction axis DR3. In addition, in this specification, the direction in which the third direction axis DR3 extends is parallel to the thickness direction, the upper surface (or front surface, upper portion surface, upper side) means a surface adjacent to the surface on which an image IM is displayed (or in a direction closer to the surface on which an image IM is displayed), and the lower surface (or rear surface, lower portion surface, lower side) means a surface spaced apart from the surface on which an image IM is displayed (or in a direction away from the surface on which an image IM is displayed). In this specification, a plane refers to a plane parallel to the plane defined by the first direction axis DR1 and the second direction axis DR2, and a cross section refers to a plane perpendicular to the plane defined by the first direction axis DR1 and the second direction axis DR2 and a plane parallel to the third direction axis (also referred to as a thickness direction) DR3.

Referring to FIG. 2, the display device DD may include a lower coating layer LC, a display module DM disposed on the lower coating layer LC, and a window WP disposed on the display module DM. In addition, the display device DD may further include a housing HAU in which the display module DM and an optical layer RPL disposed between the display module DM and the window WP are accommodated.

In the display device DD illustrated in FIGS. 1 and 2, the window WP and the housing HAU may be coupled to each other to configure the exterior of the display device DD. The housing HAU may be disposed below the display module DM. The housing HAU may include a material having a relatively high stiffness. In an embodiment, the housing HAU may include a plurality of frames and/or plates composed of glass, plastic, or metal, for example. The housing HAU may provide a predetermined accommodation space. The display module DM may be accommodated in the accommodation space so as to be protected from an external impact.

The display module DM may be activated according to an electrical signal. The display module DM is activated so as to be able to display an image IM (refer to FIG. 1) in the display region DA of the display device DD. An active region AA-DM and a peripheral region NAA-DM may be defined in the display module DM. The active region AA-DM may be activated according to an electrical signal. A pixel PX may be disposed in the active region AA-DM. The peripheral region NAA-DM may be adjacent to at least one side of the active region AA-DM. In the peripheral region NAA-DM, a circuit, a line, or the like for driving the active region AA-DM may be disposed.

The window WP may include a transmission region TA and a bezel region BZA. The transmission region TA may overlap at least a portion of the active region AA-DM of the display module DM. The transmission region TA may be an optically transparent region. An image IM (refer to FIG. 1) may be provided to a user through the transmission region TA.

The bezel region BZA may have a relatively lower light transmittance than the transmission region TA. The bezel region BZA may define the shape of the transmission region TA. The bezel region BZA may be adjacent to and surround the transmission region TA.

The bezel region BZA may have a predetermined color. The bezel region BZA may cover the peripheral region NAA-DM of the display module DM to block the peripheral region NAA-DM from being viewed from the outside. However, the embodiment of the inventive concept is not limited to what is illustrated, and the bezel region BZA may be adjacent to only one side of the transmission region TA or may be at least partially omitted.

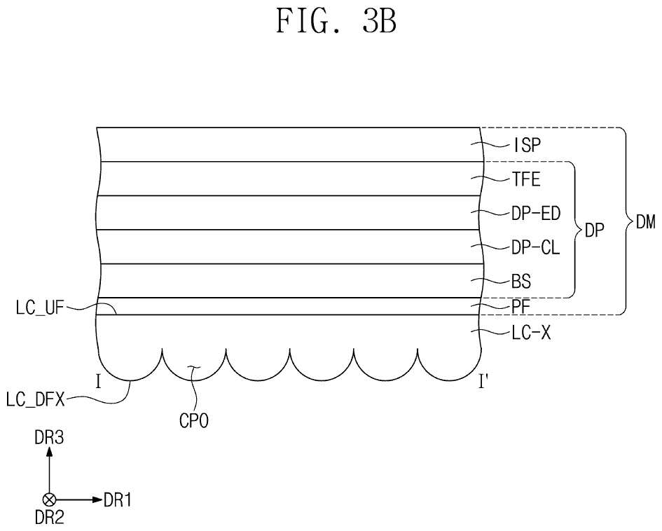

The optical layer RPL may be a reflection prevention layer that reduces the reflectance of external light incident from the outside of the display module DM. The optical layer RPL may be formed on the display module DM through a continuous process. The optical layer RPL may include a polarizing plate or a color filter layer. In an embodiment, the optical layer RPL may include at least one of a retarder, a polarizer, a polarizing film, or a polarizing filter, for example. In contrast, the optical layer RPL may include a plurality of color filters disposed in a predetermined arrangement. In an embodiment, the color filters may be arranged in consideration of the light-emitting colors of pixels included in a display panel (refer to FIG. 4), for example, which will be described later. In addition, the optical layer RPL may further include a black matrix adjacent to the color filters. Unlike what is illustrated, the optical layer RPL may be omitted.

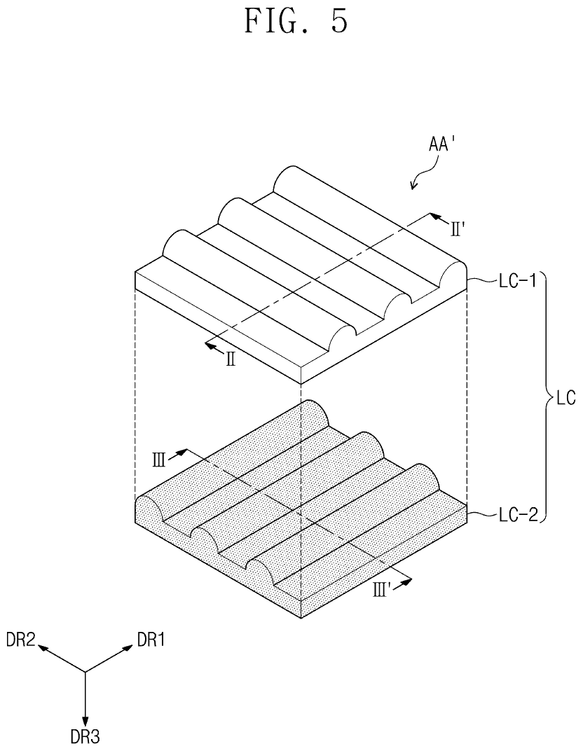

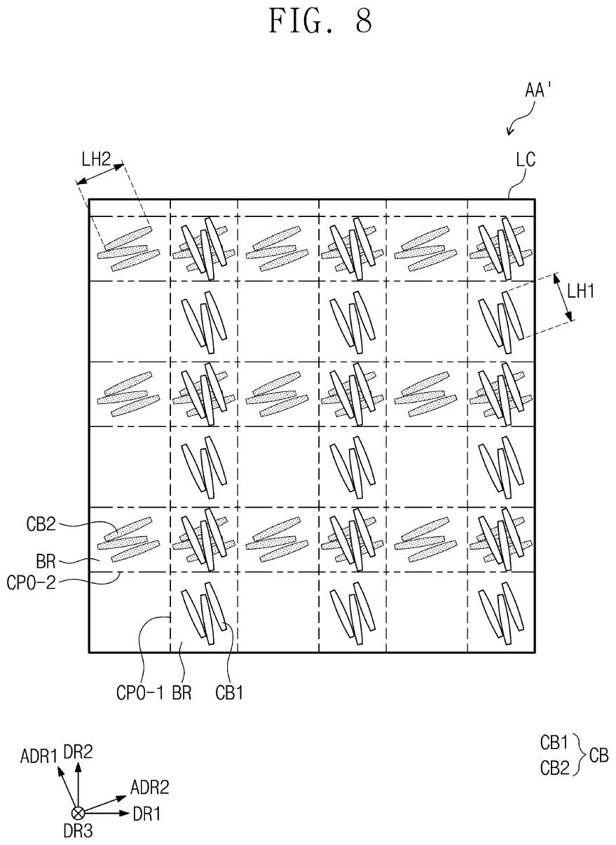

The lower coating layer LC may include a base resin BR (refer to FIGS. 6 to 8) and a plurality of carbon fillers CB (refer to FIG. 8) dispersed in the base resin BR (refer to FIGS. 6 to 8), which will be described later. The lower coating layer LC may be a functional layer that performs multiple functions, and in the display device DD in an embodiment of the inventive concept, a separate component may not be disposed below the lower coating layer LC except the housing HAU. The lower coating layer LC including the carbon fillers CB (refer to FIG. 8) may be a functional layer that performs multiple functions such as heat dissipation, light-blocking, shielding, and shock absorption. In an embodiment of the inventive concept, the display device DD including the lower coating layer LC does not include a separate heat dissipation layer, a separate light-blocking layer, a separate shielding layer, and a separate shock absorption layer below the display module DM. Accordingly, the display device DD including the lower coating layer LC in an embodiment of the inventive concept may be implemented in a thin thickness. The display device DD including the lower coating layer LC in an embodiment of the inventive concept may reduce manufacturing costs and improve manufacturing efficiency.

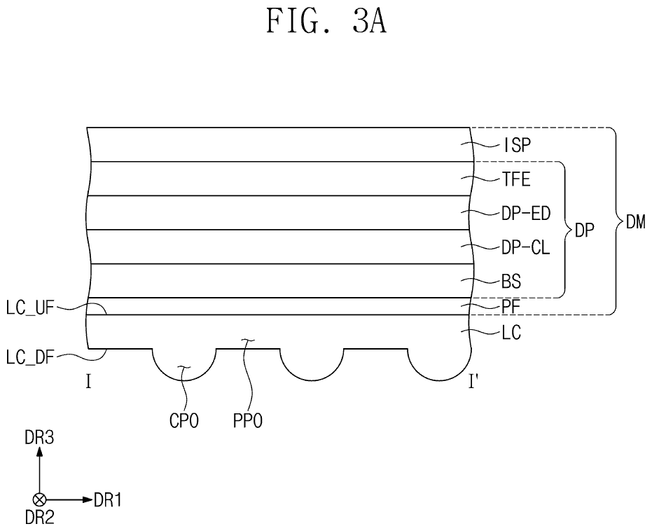

FIG. 3A is a cross-sectional view illustrating a portion corresponding to line I-I′ of FIG. 2. In FIG. 3A, for the convenience of description, the housing HAU is omitted, and the display module DM and the lower coating layer LC are illustrated.

Referring to FIG. 3A, the display module DM may include a display panel DP and an input sensing layer ISP disposed on the display panel DP. The display panel DP may be a component that substantially generates an image.

The display panel DP may be disposed on the lower coating layer LC. The lower coating layer LC may include an upper surface LC_UF and a lower surface LC_DF that opposes the upper surface LC_UF. The upper surface LC_UF of the lower coating layer LC may be adjacent to the display panel DP, and the lower surface LC_DF of the lower coating layer LC may be spaced apart from the display panel DP with the upper surface LC_UF interposed therebetween. The upper surface LC_UF of the lower coating layer LC may have a flat surface.

The lower surface LC_DF of the lower coating layer LC may include a convex portion CPO convex in a direction away from the display panel DP. In addition, the lower surface LC_DF of the lower coating layer LC may further include a flat portion PPO adjacent to the convex portion CPO. The carbon fillers CB (refer to FIG. 8) may be disposed in the convex portion CPO. The carbon fillers CB (refer to FIG. 8) may not be disposed in the flat portion PPO. The convex portion CPO and the flat portion PPO may have an integral shape. The convex portion CPO may be provided in plural, and the flat portion PPO may be provided between the plurality of convex portions. In a method of manufacturing a display device in an embodiment of the inventive concept, which will be described later, the lower coating layer LC may be formed by a dispensing method which uses a plurality of nozzles and include the convex portion CPO. The thickness of the lower coating layer LC including the convex portion CPO may not be uniform.

The display panel DP may include a base layer BS, a circuit layer DP-CL, a display element layer DP-ED, and an encapsulation layer TFE which are sequentially stacked. Unlike what is illustrated, a separate member may be disposed between two adjacent layers among the base layer BS, the circuit layer DP-CL, the display element layer DP-ED, and the encapsulation layer TFE.

The base layer BS may provide a base surface on which the circuit layer DP-CL is disposed. The base layer BS may be a flexible substrate capable of being bent, folded, or rolled. The base layer BS may be a glass substrate, a metal substrate, or a polymer substrate. However, the embodiment of the inventive concept is not limited thereto, and the base layer BS may be an inorganic layer, an organic layer, or a composite material layer.

The base layer BS may include a single layer or multiple layers. In an embodiment, the base layer BS may include a first synthetic resin layer, a single-layered or multi-layered inorganic layer, and a second synthetic resin layer disposed on the single-layered or multi-layered inorganic layer, for example. Each of the first synthetic resin layer and the second synthetic resin layer may include a polyimide-based resin. In addition, each of the first synthetic resin layer and the second synthetic resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, a “˜˜”-based resin means to include a functional group of “˜˜”.

The circuit layer DP-CL may be disposed on the base layer BS. The circuit layer DP-CL may include an insulating layer, a semiconductor pattern, a conductive pattern, a signal line, or the like. The display element layer DP-ED may be disposed on the circuit layer DP-CL. The display element layer DP-ED may include a light-emitting element ED (refer to FIG. 4) which will be described later. In an embodiment, the light-emitting element ED (refer to FIG. 4) may include an organic light-emitting material, an inorganic light-emitting material, an organic-inorganic light-emitting material, a quantum dot, a quantum rod, a micro-LED, or a nano LED, for example.

The encapsulation layer TFE may be disposed on the display element layer DP-ED. The encapsulation layer TFE may protect the display element layer DP-ED from moisture, oxygen, and foreign substances such as dust particles. The encapsulation layer TFE may include at least one inorganic layer. In an embodiment, the encapsulation layer TFE may include an inorganic layer, an organic layer, and an inorganic layer which are sequentially stacked, for example.

The input sensing layer ISP may be disposed on the display panel DP. The input sensing layer ISP may be disposed directly on the encapsulation layer TFE. In contrast, an adhesive member may be disposed between the input sensing layer ISP and the display panel DP.

In this specification, an expression “One component is directly disposed/provided on another component” means that a third component is not disposed between them. That is, the expression “One component is directly disposed/provided on another component” means that one component contacts another component.

The input sensing layer ISP may sense an external input, change it to a predetermined input signal, and provide the input signal to the display panel DP. In an embodiment, the input sensing layer ISP may be a touch sensing layer that senses a touch, for example. The input sensing layer ISP may sense a direct touch of a user, an indirect touch of a user, a direct touch of an object or an indirect touch of an object.

The input sensing layer ISP may sense at least one of the position or intensity (pressure) of a touch applied from the outside. The input sensing layer ISP may have a variety of structures or consist of various materials and is not limited to a particular embodiment. In an embodiment, the input sensing layer ISP may sense an external input by a capacitance method, for example. The display panel DP may receive an input signal from the input sensing layer ISP and generate an image corresponding to the input signal. In an embodiment, the optical layer RPL may be formed on the input sensing layer ISP through a continuous process, for example.

The display module DM may further include a panel protection layer PF disposed between the display panel DP and the lower coating layer LC. The panel protection layer PF may protect the lower portion of the display panel DP. The panel protection layer PF may include a flexible plastic material. In an embodiment, the panel protection layer PF may include polyethylene terephthalate, for example. Unlike what is illustrated, the panel protection layer PF may be omitted. When the panel protection layer PF is omitted, the display module DM may be disposed directly on the lower coating layer LC.

FIG. 3B is a cross-sectional view in another embodiment of the inventive concept. Compared to FIG. 3A, FIG. 3B only differs in the shape of a lower coating layer LC-X, and the contents of the same reference numerals as described with reference to FIG. 3A may be equally applied to those of FIG. 3B. Specifically, compared to the lower coating layer LC of FIG. 3A, the lower coating layer LC-X of FIG. 3B includes a convex portion CPO and does not include a flat portion PPO.

Referring to FIG. 3B, a lower surface LC_DFX of the lower coating layer LC-X may include a convex portion CPO and may not include a flat portion PPO. The thickness of the lower coating layer LC-X including the convex portion CPO may not be uniform. The lower coating layer LC-X of FIG. 3B may be formed by a plurality of nozzles, which are not disposed in parallel with each other in one direction, and may not include a flat portion PPO. Compared to a plurality of nozzles disposed in parallel with each other in one direction (e.g., in the first direction axis (also referred to as a first direction) DR1), a plurality of nozzles, which are not disposed in parallel with each other in one direction (e.g., in the first direction DR1), may be disposed relatively close to each other. A plurality of nozzles, which are not disposed in parallel with each other in one direction, may be disposed to form a diagonal line and may be disposed at relatively narrow intervals. Accordingly, the lower coating layer LC-X formed by a plurality of nozzles, which are not disposed in parallel with each other in one direction, may not include a flat portion PPO. This will be described in detail later when a method of manufacturing a display device in an embodiment of the inventive concept is described.

FIG. 4 is a cross-sectional view illustrating an embodiment of a display module according to the inventive concept. FIG. 4 may be a cross-sectional view specifically illustrating the configuration of the display module DM illustrated in FIGS. 3A and 3B. However, in FIG. 4, the configuration of the display module DM is exemplary, and the embodiment of the inventive concept is not limited thereto.

The display panel DP may include a pixel PX (refer to FIG. 2). The pixel PX (refer to FIG. 2) may include a transistor TR and a light-emitting element ED. The transistor TR and the light-emitting element ED may be disposed above the base layer BS. In FIG. 4, one transistor TR is illustrated, but substantially, the pixel PX (refer to FIG. 2) may include a plurality of transistors and at least one capacitor for driving the light-emitting element ED.

The circuit layer DP-CL may be disposed on the base layer BS. The circuit layer DP-CL may include a shielding electrode BML, a transistor TR, a connection electrode CNE, and a plurality of insulating layers BFL and INS1 to INS6. The plurality of insulating layers BFL and INS1 to INS6 may include a buffer layer BFL and first to sixth insulating layers INS1 to INS6. However, the stacked structure of the circuit layer DP-CL illustrated in FIG. 4 is exemplary, and the stacked structure of the circuit layer DP-CL may be changed.

The shielding electrode BML may be disposed on the base layer BS. The shielding electrode BML may overlap the transistor TR. The shielding electrode BML may block light incident toward the transistor TR from the lower portion of the display panel DP to protect the transistor TR. The shielding electrode BML may include a conductive material. When a voltage is applied to the shielding electrode BML, the threshold voltage of the transistor TR disposed on the shielding electrode BML may be maintained. However, the embodiment of the inventive concept is not limited thereto, and the shielding electrode BML may be a floating electrode. The shielding electrode BML may be omitted.

The buffer layer BFL may be disposed on the base layer BS to cover the shielding electrode BML. The buffer layer BFL may include an inorganic layer. The buffer layer BFL may improve the bonding strength between the base layer BS and the semiconductor pattern or the conductive pattern disposed on the buffer layer BFL.

The transistor TR may include a source S1, a channel C1, a drain D1, and a gate G1. The source S1, the channel C1, and the drain D1 of the transistor TR may be formed from the semiconductor pattern. The semiconductor pattern of the transistor TR may include polysilicon, amorphous silicon, or metal oxide, and as long as a material has semiconductor properties, it may be applied without limitation, and the inventive concept is not limited to a particular embodiment.

The semiconductor pattern may include a plurality of regions divided according to the level of conductivity. A region of the semiconductor pattern, which is doped with a dopant or in which metal oxide is reduced, may have relatively high conductivity and substantially serve as a source electrode and a drain electrode of the transistor TR. A region with relatively high conductivity in the semiconductor pattern may correspond to the source S1 and drain D1 of the transistor TR. A region of the semiconductor pattern, which is undoped or doped at a relatively low concentration or has relatively low conductivity due to non-reduced metal oxide, may correspond to the channel C1 (or active) of the transistor TR.

The first insulating layer INS1 may cover the semiconductor pattern of the transistor TR and be disposed on the buffer layer BFL. The gate G1 of the transistor TR may be disposed on the first insulating layer INS1. The gate G1 may overlap the channel C1 of the transistor TR. The gate G1 may function as a mask in a process of doping the semiconductor pattern of the transistor TR.

The second insulating layer INS2 may cover the gate G1 and be disposed on the first insulating layer INS1. The third insulating layer INS3 may be disposed on the second insulating layer INS2.

The connection electrodes CNE may include a first connection electrode CNE1 and a second connection electrode CNE2 for electrically connecting the transistor TR and the light-emitting element ED to each other. However, the configuration of the connection electrode CNE electrically connecting the transistor TR and the light-emitting element ED to each other is not limited thereto, and one of the first and second connection electrodes CNE1 and CNE2 may be omitted, or an additional connection electrode may be further included.

The first connection electrode CNE1 may be disposed on the third insulating layer INS3. The first connection electrode CNE1 may be connected to the drain D1 through a first contact hole CH1 passing through the first to third insulating layers INS1 to INS3. The fourth insulating layer INS4 may cover the first connection electrode CNE1 and be disposed on the third insulating layer INS3. The fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 through a second contact hole CH2 passing through the fourth and fifth insulating layers INS4 and INS5. The sixth insulating layer INS6 may cover the second connection electrode CNE2 and be disposed on the fifth insulating layer INS5.

Each of the first to sixth insulating layers INS1 to INS6 may include an inorganic layer or an organic layer. In an embodiment, the inorganic layer may include at least one of aluminum oxide, titanium oxide, silicon oxide, silicon oxynitride, zirconium oxide, or hafnium oxide, for example. The organic layer may include at least any one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin.

The display element layer DP-ED may include a pixel defining film PDL and a light-emitting element ED. The light-emitting element ED may include a first electrode AE, a hole control layer HCL, a light-emitting layer EML, an electron control layer TCL, and a second electrode CE.

The first electrode AE may be disposed on the sixth insulating layer INS6. The first electrode AE may be connected to the second connection electrode CNE2 through a third contact hole CH3 passing through the sixth insulating layer INS6. The first electrode AE may be electrically connected to the drain D1 of the transistor TR through the first and second connection electrodes CNE1 and CNE2.

The first electrode AE may include or consist of a metal material, a metal alloy, or a conductive compound. The first electrode AE may be an anode or a cathode. However, the embodiment of the inventive concept is not limited thereto. In addition, the first electrode AE may be a pixel electrode. The first electrode AE may be a transmissive electrode, a semi-transmissive electrode, or a reflective electrode. The first electrode AE may include at least one selected from the group including Ag, Mg, Cu, Al, Pt, Pd, Au, Ni, Nd, Ir, Cr, Li, Ca, LiF, Mo, Ti, W, In, Sn, and Zn, a compound of two or more selected therefrom, a combination of two or more selected therefrom, or an oxide thereof.

When the first electrode AE is a transmissive electrode, the first electrode AE may include a transparent metal oxide such as an indium tin oxide (“ITO”), an indium zinc oxide (“IZO”), a zinc oxide (ZnO), an indium tin zinc oxide (“ITZO”), or the like. When the first electrode AE is a semi-transmissive electrode or a reflective electrode, the first electrode AE may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or combination thereof (e.g., a combination of Ag and Mg). In an alternative embodiment, the first electrode AE may have a multi-layered structure including: a reflective film or semi-transmissive film including or consisting of the above materials; and a transparent conductive film including or consisting of an ITO, an IZO, a zinc oxide (ZnO), an ITZO, or the like. In an embodiment, the first electrode AE may have a three-layer structure of ITO/Ag/ITO, for example, but the embodiment of the inventive concept is not limited thereto. In addition, the embodiment of the inventive concept is not limited thereto, and the first electrode AE may include an above-described metallic material, a combination of two or more metallic materials selected from among the above-described metallic materials, an oxide of the above-described metallic materials, or the like.

The pixel defining film PDL may be disposed on the sixth insulating layer INS6. A light-emitting opening PX_OP exposing a portion of the first electrode AE may be defined in the pixel defining film PDL. The portion of the first electrode AE exposed by the light-emitting opening PX_OP may be defined as a light-emitting region LA.

A region in which the pixel defining film PDL is disposed may correspond to a light-blocking region NLA. The light-blocking region NLA may surround the light-emitting region LA within the active region AA-DM.

The hole control layer HCL may be disposed on the first electrode AE and the pixel defining film PDL. The hole control layer HCL may be provided as a common layer overlapping the light-emitting region LA and the light-blocking region NLA. The hole control layer HCL may include at least one of a hole transport layer, a hole injection layer, or an electron blocking layer. The hole control layer HCL may include a known hole injection material and/or a known hole transport material.

The light-emitting layer EML may be disposed on the hole control layer HCL. The light-emitting layer EML may be disposed in a region corresponding to the light-emitting opening PX_OP. In contrast, the light-emitting layer EML may be provided as a common layer. The light-emitting layer EML may include an organic material and/or an inorganic material. The light-emitting layer EML may emit color light of any one of red, green, and blue.

The electron control layer TCL may be disposed on the light-emitting layer EML. The electron control layer TCL may be provided as a common layer overlapping the light-emitting region LA and the light-blocking region NLA. The electron control layer TCL may include at least one of an electron transport layer, an electron injection layer, or a hole blocking layer. The electron control layer TCL may include a known electron injection material and/or a known electron transport material.

The second electrode CE may be disposed on the electron control layer TCL. The second electrode CE may be provided as a common layer overlapping the light-emitting region LA and the light-blocking region NLA. The second electrode CE may be commonly disposed in the pixels PX (refer to FIG. 2) and apply a voltage to the pixels PX (refer to FIG. 2).

The second electrode CE may be a common electrode. The second electrode CE may be a cathode or an anode, but the embodiment of the inventive concept is not limited thereto. In an embodiment, when the first electrode AE is an anode, the second electrode CE may be a cathode, and when the first electrode AE is a cathode, the second electrode CE may be an anode, for example.

The second electrode CE may be a transmissive electrode, a semi-transmissive electrode, or a reflective electrode. When the second electrode CE is a transmissive electrode, the second electrode CE may consist of a transparent metal oxide such as an ITO, an IZO, a zinc oxide (ZnO), or ITZO.

When the second electrode CE is a semi-transmissive electrode or a reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, or a compound or combination thereof (e.g., AgMg, AgYb, and MgYb). In an alternative embodiment, the second electrode CE may have a multi-layered structure including: a reflective film or semi-transmissive film including or consisting of the above materials; and a transparent conductive film including or consisting of an ITO, an IZO, a zinc oxide (ZnO), an ITZO, or the like. In an embodiment, the second electrode CE may include an above-described metallic material, a combination of two or more metallic materials selected from among the above-described metallic materials, an oxide of the above-described metallic materials, or the like, for example.

The encapsulation layer TFE may be disposed on the second electrode CE and cover the light-emitting element ED. The encapsulation layer TFE may include a plurality of thin films. In an embodiment, the encapsulation layer TFE may include inorganic films disposed on the second electrode CE and an organic film disposed between the inorganic films, for example. The inorganic film may protect the light-emitting element ED from moisture/oxygen, and the organic film may protect the light-emitting element ED from foreign substances such as dust particles.

The input sensing layer ISP may include a first sensing insulating layer IL1, a second sensing insulating layer IL2, and a third sensing insulating layer IL3. The input sensing layer ISP may include at least one conductive layer disposed on the sensing insulating layers. The input sensing layer ISP may include a first conductive layer CDL1, and a second conductive layer CDL2.

The first sensing insulating layer IL1 may be disposed on the encapsulation layer TFE. The first sensing insulating layer IL1 may include at least one inorganic insulating layer. The first sensing insulating layer IL1 may contact the encapsulation layer TFE. In contrast, the first sensing insulating layer IL1 may be omitted, and in this case, the first conductive layer CDL1 may contact the encapsulation layer TFE.

The first conductive layer CDL1 may be disposed on the first sensing insulating layer IL1. The first conductive layer CDL1 may include a plurality of first conductive patterns. The plurality of first conductive patterns may be disposed on the first sensing insulating layer IL1. The second sensing insulating layer IL2 may be disposed on the first sensing insulating layer IL1 to cover at least a portion of the first conductive layer CDL1.

The second conductive layer CDL2 may be disposed on the second sensing insulating layer IL2. The second conductive layer CDL2 may include a plurality of second conductive patterns. The plurality of second conductive patterns may be disposed on the second sensing insulating layer IL2. The plurality of second conductive patterns may be respectively connected to the plurality of first conductive patterns through contact holes defined in the second sensing insulating layer IL2.

Each of the plurality of first conductive patterns of the first conductive layer CDL1 and the plurality of second conductive patterns of the second conductive layer CDL2 may be disposed to correspond to the light-blocking region NLA. Each of the plurality of first conductive patterns of the first conductive layer CDL1 and the plurality of second conductive patterns of the second conductive layer CDL2 may correspond to a mesh pattern.

The third sensing insulating layer IL3 may be disposed on the second sensing insulating layer IL2 and cover the second conductive layer CDL2. Each of the second sensing insulating layer IL2 and the third sensing insulating layer IL3 may include an inorganic insulating layer or an organic insulating layer.

Each of the first conductive layer CDL1 and the second conductive layer CDL2 may have a single-layered structure or a multi-layered structure in which layers are stacked along the third direction axis (also referred to as a third direction) DR3. The conductive layers CDL1 and CDL2 having a single-layered structure may include a metal layer or a transparent conductive layer. The metal layer may include molybdenum, silver, titanium, copper, aluminum, or alloys thereof. The transparent conductive layer may include a transparent conductive oxide such as ITO, IZO, zinc oxide (ZnO), and IZTO. In addition, the transparent conductive layer may include a conductive polymer such as poly(3,4-ethylenedioxythiophene) (“PEDOT”), metal nanowire, graphene, or the like.

The conductive layers CDL1 and CDL2 having a multi-layered structure may include metal layers. In an embodiment, the metal layers may have a three-layer structure of titanium (Ti)/aluminum (Al)/titanium (Ti), for example. The conductive layers CDL1 and CDL2 having a multi-layered structure may include at least one metal layer and at least one transparent conductive layer.

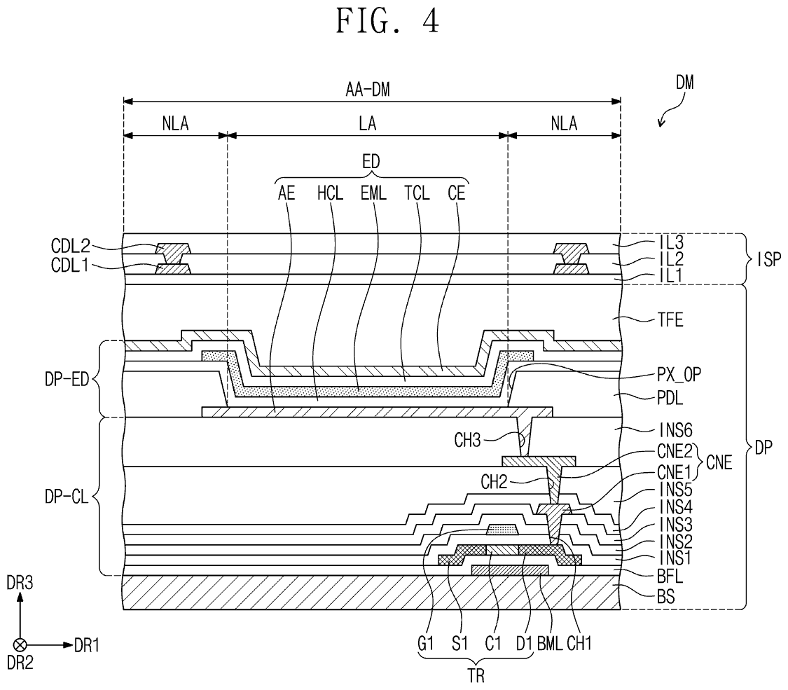

FIG. 5 is a perspective view illustrating a portion corresponding to region AA′ of FIG. 2. FIG. 5 may be a perspective view illustrating an embodiment of a lower coating layer LC according to the inventive concept. Hereinafter, the description of the lower coating layer LC may also be applied to the lower coating layer LC-X illustrated in FIG. 3B, except that the lower coating layer LC includes a flat portion PPO.

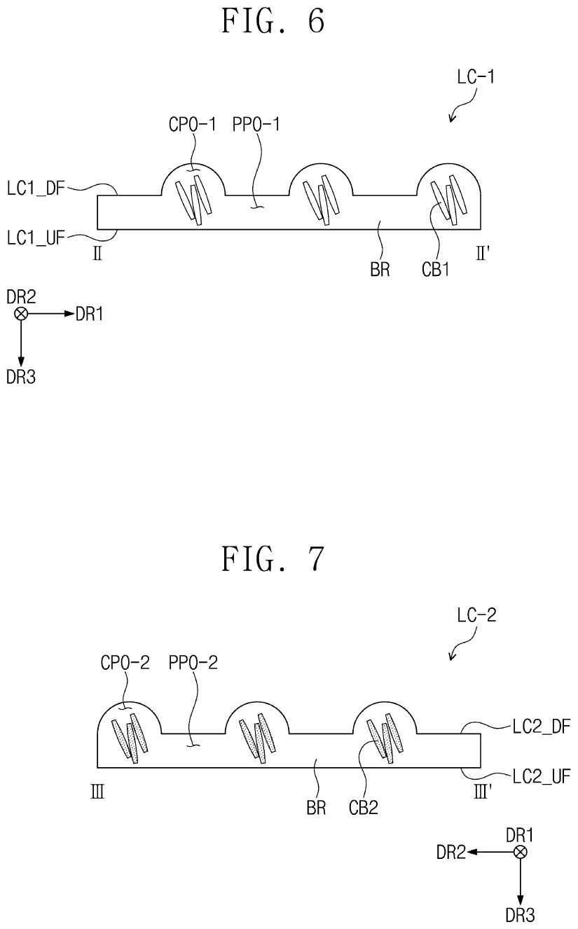

Referring to FIG. 5, the lower coating layer LC may include a first coating layer LC-1 and a second coating layer LC-2. Based on the thickness direction DR3, the second coating layer LC-2 may be disposed below the first coating layer LC-1. That is, the second coating layer LC-2 may be adjacent to the display module DM (refer to FIG. 2), and the first coating layer LC-1 may be spaced apart from the display module (refer to FIG. 2) with the second coating layer LC-2 interposed therebetween. The second coating layer LC-2 may be disposed between the first coating layer LC-1 and the display panel DP (refer to FIG. 3A). In an embodiment, the second coating layer LC-2 may contact the display panel DP (refer to FIG. 3A), for example. FIG. 6 is a cross-sectional view illustrating a portion corresponding to line II-II′ of FIG. 5. FIG. 6 may be a cross-sectional view illustrating an embodiment of a first coating layer LC-1 according to the inventive concept. FIG. 7 is a cross-sectional view illustrating a portion corresponding to line III-III′ of FIG. 5. FIG. 7 may be a cross-sectional view illustrating a second coating layer LC-2 according to the inventive concept. Hereinafter, descriptions will be provided with reference to FIGS. 5 to 7.

Referring to FIG. 6, the first coating layer LC-1 may include a first surface LC1_DF and a first opposite surface LC1_UF which are spaced apart from each other in the thickness direction DR3. In the first coating layer LC-1, the first surface LC1_DF may be a lower surface spaced apart from the display panel DP (refer to FIG. 3A), and the first opposite surface LC1_UF may be an upper surface adjacent to the display panel DP (refer to FIG. 3A). The first surface LC1_DF of the first coating layer LC-1 may be spaced apart from the display panel DP (refer to FIG. 3A) with the first opposite surface LC1_UF of the first coating layer LC-1 interposed therebetween. The first opposite surface LC1_UF of the first coating layer LC-1 may be a flat surface. In contrast, the first opposite surface LC1_UF of the first coating layer LC-1 may not be a flat surface.

The lower surface LC_DF (refer to FIG. 3A) of the lower coating layer LC may be the first surface LC1_DF of the first coating layer LC-1. The first surface LC1_DF of the first coating layer LC-1 may include a first convex portion CPO-1. The first convex portion CPO-1 of the first coating layer LC-1 may extend along the second direction axis (also referred to as a second direction) DR2. The first surface LC1_DF of the first coating layer LC-1 may further include a first flat portion PPO-1. The first convex portion CPO-1 and the first flat portion PPO-1 may have an integral shape. In the lower coating layer LC, the convex portion CPO may be the first convex portion CPO-1 of the first coating layer LC-1. In the lower coating layer LC, the flat portion PPO may be the first flat portion PPO-1 of the first coating layer LC-1.

The first coating layer LC-1 may include a base resin BR and a plurality of first sub-carbon fillers CB1 dispersed in the base resin BR. Each of the first sub-carbon fillers CB1 may be a carbon fiber. In the first coating layer LC-1, the first sub-carbon fillers CB1 may be disposed in the first convex portion CPO-1 and may not be disposed in the first flat portion PPO-1. The first convex portion CPO-1 may be provided in plural, and the first sub-carbon fillers CB1 may be disposed in each of the plurality of first convex portions CPO-1. FIG. 6 illustrates that three first sub-carbon fillers CB1 are disposed in each of the first convex portions CPO-1, but the embodiment of the inventive concept is not limited thereto.

Referring to FIG. 7, the second coating layer LC-2 may include a second surface LC2_DF and a second opposite surface LC2_UF which are spaced apart from each other in the thickness direction DR3. In the second coating layer LC-2, the second surface LC2_DF may be a lower surface spaced apart from the display panel DP (refer to FIG. 3A), and the second opposite surface LC2_UF may be an upper surface adjacent to the display panel DP (refer to FIG. 3A). The second surface LC2_DF of the second coating layer LC-2 may be spaced apart from the display panel DP (refer to FIG. 3A) with the second opposite surface LC2_UF of the second coating layer LC-2 interposed therebetween. The second opposite surface LC2_UF of the second coating layer LC-2 may be a flat surface. In contrast, the second opposite surface LC2_UF of the second coating layer LC-2 may not be a flat surface.

The upper surface LC_UF (refer to FIG. 3A) of the lower coating layer LC may be the second opposite surface LC2_UF of the second coating layer LC-2. The second surface LC2_DF of the second coating layer LC-2 may include a second convex portion CPO-2. The second convex portion CPO-2 of the second coating layer LC-2 may extend along the first direction DR1. A direction (i.e., the second direction DR2) in which the first convex portion CPO-1 of the first coating layer LC-1 extends and a direction (i.e., the first direction DR1) in which the second convex portion CPO-2 of the second coating layer LC-2 extends may cross each other. The second surface LC2_DF of the second coating layer LC-2 may further include a second flat portion PPO-2. The second convex portion CPO-2 and the second flat portion PPO-2 may have an integral shape.

The second coating layer LC-2 may include a base resin BR and a plurality of second sub-carbon fillers CB2 dispersed in the base resin BR. Each of the second sub-carbon fillers CB2 may be a carbon fiber. In the second coating layer LC-2, the second sub-carbon fillers CB2 may be disposed in the second convex portion CPO-2 and may not be disposed in the second flat portion PPO-2. The second convex portion CPO-2 may be provided in plural, and the second sub-carbon fillers CB2 may be disposed in each of the plurality of second convex portions CPO-2. FIG. 7 illustrates that three second sub-carbon fillers CB2 are disposed in each of the second convex portions CPO-2, but the embodiment of the inventive concept is not limited thereto.

The base resin BR of the first coating layer LC-1 and the base resin BR of the second coating layer LC-2 may include a same material as each other. The base resin BR may be a photocurable resin. The base resin BR may include at least one of an epoxy-based resin, an acrylic-based resin, a urethane-based resin, or a silicone-based resin. The first sub-carbon filler CB1 of the first coating layer LC-1 and the second sub-carbon filler CB2 of the second coating layer LC-2 may be the same carbon fiber. The first sub-carbon filler CB1 of the first coating layer LC-1 and the second sub-carbon filler CB2 of the second coating layer LC-2 are the same carbon fibers, but their arrangement directions may be different from each other.

FIG. 8 is a plan view illustrating a portion corresponding to region AA′ of FIG. 2. FIG. 8 may be a plan view illustrating the lower coating layer LC illustrated in FIG. 5.

Referring to FIG. 8, the lower coating layer LC may include a base resin BR and carbon fillers CB dispersed in the base resin BR. The carbon fillers CB may include first sub-carbon fillers CB1 and second sub-carbon fillers CB2. With respect to the total weight (100 wt %) of the lower coating layer LC, the weight of the carbon fillers CB may be about 50 wt % to about 90 wt %. With respect to the total weight (100 wt %) of the lower coating layer LC, the lower coating layer LC including about 50 wt % to about 90 wt % of the carbon fillers CB may exhibit excellent heat dissipation, light-blocking, shielding, and shock absorption properties. Accordingly, the display device DD (refer to FIG. 2) in an embodiment of the inventive concept may exhibit excellent reliability. In addition, with respect to the total weight (100 wt %) of the lower coating layer LC, the lower coating layer LC including about 50 wt % to about 90 wt % of the carbon fillers CB may exhibit properties in which it is easily formed by a dispensing method in a method of manufacturing a display device in an embodiment of the inventive concept, which will be described later.

In contrast, with respect to the total weight (100 wt %) of the lower coating layer, the lower coating layer including less than 50 wt % of the carbon fillers exhibits reduced heat dissipation, light-blocking, shielding, and shock absorption properties. With respect to the total weight (100 wt %) of the lower coating layer, the lower coating layer including more than 90 wt % of the carbon fillers is not suitable for being formed by a dispensing method in a method of manufacturing a display device in an embodiment of the inventive concept, which will be described later.

Each of the first sub-carbon fillers CB1 may be a carbon fiber having a rod shape. A length LH1 of the long side of each of the first sub-carbon fillers CB1 may be about 10 micrometers (μm) to about 200 μm. The length LH1 of the long side of each of the first sub-carbon fillers CB1 may be about 10 μm to about 50 μm or about 150 μm to about 200 μm. The long side of each of the first sub-carbon fillers CB1 may be parallel to a first arrangement direction ADR1. Each of the second sub-carbon fillers CB2 may be a carbon fiber having a rod shape. A length LH2 of the long side of each of the second sub-carbon fillers CB2 may be about 10 μm to about 200 μm. The length LH2 of the long side of each of the second sub-carbon fillers CB2 may be about 10 μm to about 50 μm or about 150 μm to about 200 μm. The long side of each of the second sub-carbon fillers CB2 may be parallel to a second arrangement direction ADR2. In an embodiment, the lower coating layer LC illustrated in FIG. 5 may include the first and second sub-carbon fillers CB1 and CB2 with long sides having the lengths LH1 and LH2 of about 150 μm to about 200 μm, for example.

The first sub-carbon fillers CB1 may be disposed in the first convex portion CPO-1, and the second sub-carbon fillers CB2 may be disposed in the second convex portion CPO-2. In FIG. 8, for the convenience of description, the first convex portion CPO-1 and the second convex portion CPO-2 disposed below the first convex portion CPO-1 are illustrated, and the boundary line of each of the first convex portion CPO-1 and the second convex portion CPO-2 is illustrated as a dotted line.

The first sub-carbon fillers CB1 may be disposed in the first arrangement direction ADR1. The first sub-carbon fillers CB1 may be disposed to form the first arrangement direction ADR1. The first sub-carbon fillers CB1 may be disposed in a line in the second direction DR2. The second sub-carbon fillers CB2 may be disposed in the second arrangement direction ADR2. The second sub-carbon fillers CB2 may be disposed to form the second arrangement direction ADR2. The second sub-carbon fillers CB2 may be disposed in a line in the first direction DR1. The first arrangement direction ADR1 and the second arrangement direction ADR2 may cross each other in a plan view. The first arrangement direction ADR1 may form an acute angle counterclockwise with respect to the second direction DR2. The second arrangement direction ADR2 may form an acute angle counterclockwise with respect to the first direction DR1. However, this is merely one of embodiments, and the first and second arrangement directions ADR1 and ADR2 are not limited to a particular embodiment as long as they cross each other in a plan view.

In an embodiment of the inventive concept, by including the carbon fillers CB disposed in arrangement directions that cross each other, the lower coating layer LC may exhibit excellent stiffness and impact resistance. The carbon fillers CB disposed in arrangement directions that cross each other may form a fabric shape. Accordingly, the lower coating layer LC may exhibit excellent stiffness and impact resistance. In addition, when the display panel DP has a relatively thin thickness, the lower coating layer LC in an embodiment of the inventive concept may stably support the display panel DP.

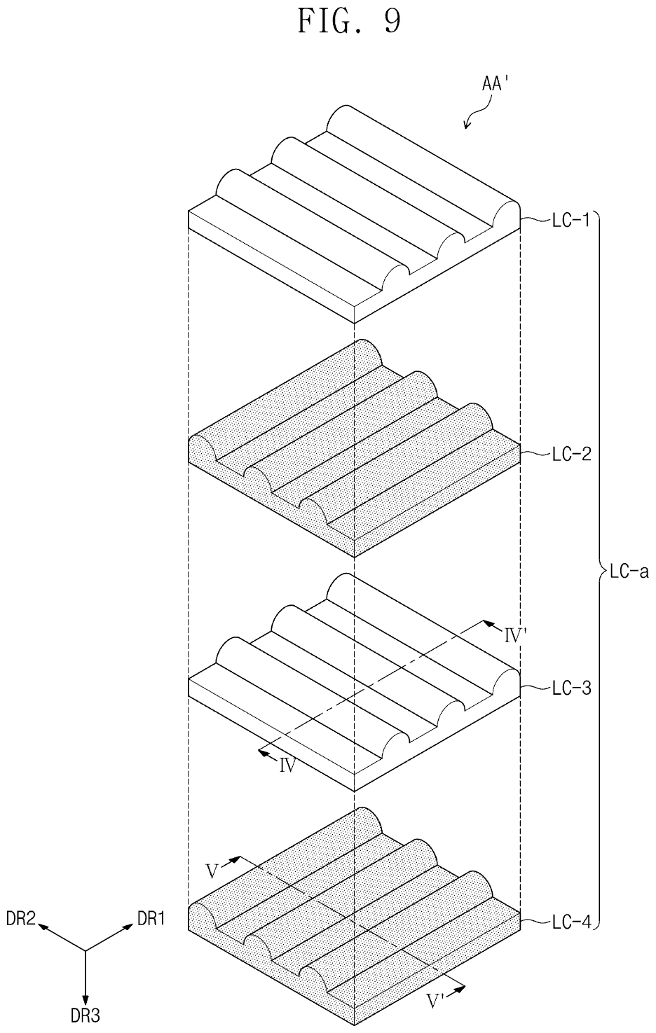

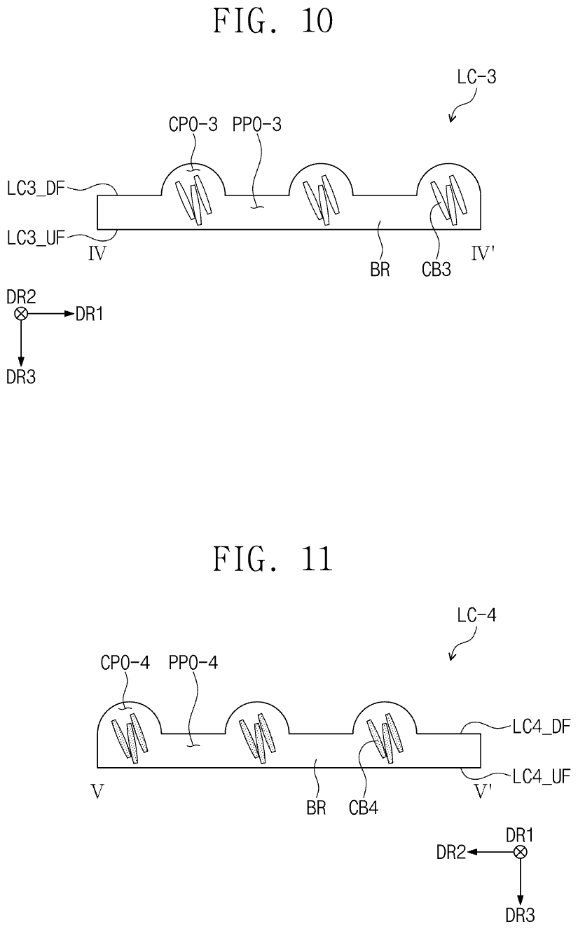

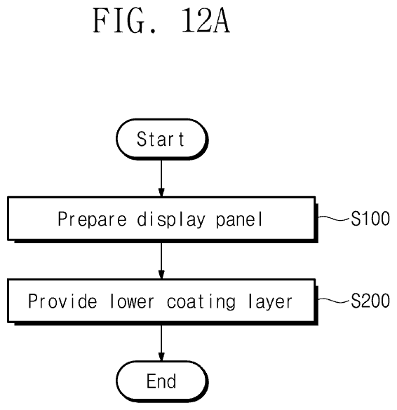

FIG. 9 is a perspective view illustrating an embodiment of a lower coating layer in another embodiment of the inventive concept. Compared to the lower coating layer LC illustrated in FIG. 5, a lower coating layer LC-a illustrated in FIG. 9 is different in that it further includes third and fourth coating layers LC-3 and LC-4. FIG. 10 is a cross-sectional view illustrating a portion corresponding to line IV-IV′ of FIG. 9. FIG. 10 may be a cross-sectional view illustrating an embodiment of the third coating layer LC-3 according to the inventive concept. FIG. 11 is a cross-sectional view illustrating an embodiment of a portion corresponding to line V-V′ of FIG. 9. FIG. 11 may be a cross-sectional view illustrating an embodiment of the fourth coating layer LC-4 according to the inventive concept. Hereinafter, descriptions will be provided with reference to FIGS. 9 to 11 together. In the descriptions of FIGS. 9 to 11, the contents overlapping those described with reference to FIGS. 1 to 8 will not be described again, and differences will be mainly described. Hereinafter, the description of the lower coating layer LC-a may also be applied to the lower coating layer LC-X illustrated in FIG. 3B except that the lower coating layer LC-a includes flat portions PPO-3 and PPO-4 (refer to FIGS. 10 and 11).

Referring to FIG. 9, the lower coating layer LC-a may include first to fourth coating layers LC-1, LC-2, LC-3, and LC-4. Based on the thickness direction DR3, the third coating layer LC-3 and the fourth coating layer LC-4 may be disposed above the second coating layer LC-2. Based on the thickness direction DR3, the fourth coating layer LC-4 may be disposed on the upper side of the third coating layer LC-3. The third coating layer LC-3 may be disposed between the second coating layer LC-2 and the display panel DP (refer to FIG. 3A). The fourth coating layer LC-4 may be disposed between the third coating layer LC-3 and the display panel DP (refer to FIG. 3A). The fourth coating layer LC-4 may be adjacent to the display panel DP (refer to FIG. 3A), and the third coating layer LC-3 may be spaced apart from the display panel DP (refer to FIG. 3A) with the fourth coating layer LC-4 interposed therebetween. The fourth coating layer LC-4 may be spaced apart from the second coating layer LC-2 with the third coating layer LC-3 interposed therebetween. The third coating layer LC-3 may be spaced apart from the first coating layer LC-1 with the second coating layer LC-2 interposed therebetween. The carbon filler CB (refer to FIG. 8) of the lower coating layer LC-a may further include third and fourth sub-carbon fillers CB3 and CB4.

The third coating layer LC-3 may include a third surface LC3_DF and a third opposite surface LC3_UF spaced apart from each other in the thickness direction DR3. In the third coating layer LC-3, the third surface LC3_DF may be a lower surface spaced apart from the display panel DP (refer to FIG. 3A), and the third opposite surface LC3_UF may be an upper surface adjacent to the display panel DP (refer to FIG. 3A). The third surface LC3_DF of the third coating layer LC-3 may be spaced apart from the display panel DP (refer to FIG. 3A) with the third opposite surface LC3_UF of the third coating layer LC-3 interposed therebetween. The third opposite surface LC3_UF of the third coating layer LC-3 may be a flat surface. In contrast, the third opposite surface LC3_UF of the third coating layer LC-3 may not be a flat surface.

The third surface LC3_DF of the third coating layer LC-3 may include a third convex portion CPO-3. The third convex portion CPO-3 of the third coating layer LC-3 may extend along the second direction DR2. The third convex portion CPO-3 of the third coating layer LC-3 may extend in the same direction (e.g., the second direction DR2) as that of the first convex portion CPO-1 of the first coating layer LC-1 (refer to FIGS. 5 and 6). The third surface LC3_DF of the third coating layer LC-3 may further include a third flat portion PPO-3. The third convex portion CPO-3 and the third flat portion PPO-3 may have an integral shape.

The third coating layer LC-3 may include a base resin BR and a plurality of third sub-carbon fillers CB3 dispersed in the base resin BR. Each of the third sub-carbon fillers CB3 may be a carbon fiber. In the third coating layer LC-3, the third sub-carbon fillers CB3 may be disposed in the third convex portion CPO-3 and may not be disposed in the third flat portion PPO-3. The third convex portion CPO-3 may be provided in plural, and the third sub-carbon fillers CB3 may be disposed in each of the plurality of third convex portions CPO-3. FIG. 10 illustrates that three third sub-carbon fillers CB3s are disposed in each of the third convex portions CPO-3, but the embodiment of the inventive concept is not limited thereto.

The arrangement direction of the third sub-carbon fillers CB3 may be the same as the first arrangement direction ADR1 of the first sub-carbon fillers CB1 illustrated in FIG. 8. The third sub-carbon fillers CB3 may be the same carbon fiber as the first and second sub-carbon fillers CB1 and CB2. The base resin BR of the third coating layer LC-3 may include the same material as that of the base resin BR of the first and second coating layers LC-1 and LC-2.

The fourth coating layer LC-4 may include a fourth surface LC4_DF and a fourth opposite surface LC4_UF spaced apart from each other in the thickness direction DR3. In the fourth coating layer LC-4, the fourth surface LC4_DF may be a lower surface spaced apart from the display panel DP (refer to FIG. 3A), and the fourth opposite surface LC4_UF may be an upper surface adjacent to the display panel DP (refer to FIG. 3A). The fourth surface LC4_DF of the fourth coating layer LC-4 may be spaced apart from the display panel DP (refer to FIG. 3A) with the fourth opposite surface LC4_UF of the fourth coating layer LC-4 interposed therebetween. The fourth opposite surface LC4_UF of the fourth coating layer LC-4 may be a flat surface. In contrast, the fourth opposite surface LC4_UF of the fourth coating layer LC-4 may not be a flat surface.

The fourth surface LC4_DF of the fourth coating layer LC-4 may include a fourth convex portion CPO-4. The fourth convex portion CPO-4 of the fourth coating layer LC-4 may extend along the first direction DR1. The fourth convex portion CPO-4 of the fourth coating layer LC-4 may extend in the same direction (e.g., the first direction DR1) as that of the second convex portion CPO-2 of the second coating layer LC-2 (refer to FIGS. 5 and 7). The fourth surface LC4_DF of the fourth coating layer LC-4 may further include a fourth flat portion PPO-4. The fourth convex portion CPO-4 and the fourth flat portion PPO-4 may have an integral shape.

The fourth coating layer LC-4 may include a base resin BR and a plurality of four sub-carbon fillers CB4 dispersed in the base resin BR. Each of the four sub-carbon fillers CB4 may be a carbon fiber. In the fourth coating layer LC-4, the fourth sub-carbon fillers CB4 may be disposed in the fourth convex portion CPO-4 and may not be disposed in the fourth flat portion PPO-4. The fourth convex portion CPO-4 may be provided in plural, and the fourth sub-carbon fillers CB4 may be disposed in each of the plurality of fourth convex portions CPO-4. FIG. 11 illustrates that three fourth sub-carbon fillers CB4 are disposed in each of the fourth convex portions CPO-4, but the embodiment of the inventive concept is not limited thereto.

The arrangement direction of the fourth sub-carbon fillers CB4 may be the same as the second arrangement direction ADR2 of the second sub-carbon fillers CB2 illustrated in FIG. 8. The fourth sub-carbon fillers CB4 may be the same carbon fiber as the first to third sub-carbon fillers CB1, CB2, and CB3. The third and fourth sub-carbon fillers CB3 and CB4 may be the same carbon fiber and only their arrangement directions may be different from each other. The base resin BR of the fourth coating layer LC-4 may include the same material as that of the base resin BR of the first to third coating layers LC-1, LC-2, and LC-3.

The contents of the first and second sub-carbon fillers CB1 and CB2 described with reference to FIG. 8 may be respectively applied to the third and fourth sub-carbon fillers CB3 and CB4. Each of the third and fourth sub-carbon fillers CB3 and CB4 may be a carbon fiber having a rod shape. The length of the long side of each of the third sub-carbon fillers CB3 may be about 10 μm to about 200 μm. The length of the long side of each of the third sub-carbon fillers CB3 may be about 10 μm to about 50 μm or about 150 μm to about 200 μm. The length of the long side of each the third sub-carbon fillers CB3 is the same as the length LH1 of the long side of each of the first sub-carbon fillers CB1, and the same reference numeral is used for them.

The length of the long side of each of the fourth sub-carbon fillers CB4 may be about 10 μm to about 200 μm. The length of the long side of each of the fourth sub-carbon fillers CB4 may be about 10 μm to about 50 μm or about 150 μm to about 200 μm. The length of the long side of each of the fourth sub-carbon fillers CB4 is the same as the length LH2 of the long side of each of the second sub-carbon fillers CB2, and the same reference numeral is used for them. In an embodiment, the lower coating layer LC-a illustrated in FIG. 9 may include the first to fourth sub-carbon fillers CB1, CB2, CB3, and CB4 with long sides having the lengths LH1 and LH2 of about 10 μm to about 50 μm, for example.

The lower coating layer LC-a including the plurality of sub-carbon fillers CB1, CB2, CB3, and CB4 disposed in arrangement directions that cross each other may exhibit excellent stiffness and impact resistance. The sub-carbon fillers CB1, CB2, CB3, and CB4 disposed in arrangement directions that cross each other may form a fabric shape. Accordingly, the lower coating layer LC-a may exhibit excellent stiffness and impact resistance. The display device DD (refer to FIG. 1) in an embodiment of the inventive concept, which includes the lower coating layer LC-a, may exhibit excellent reliability.

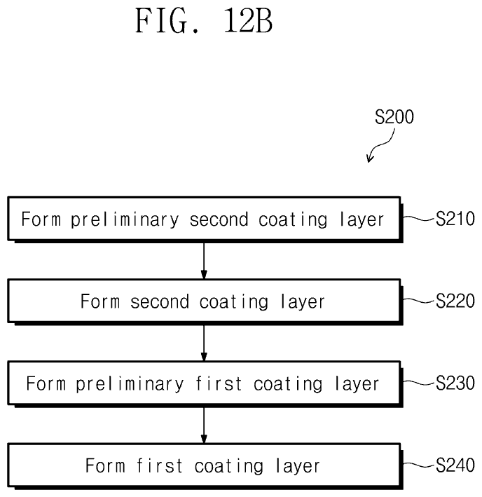

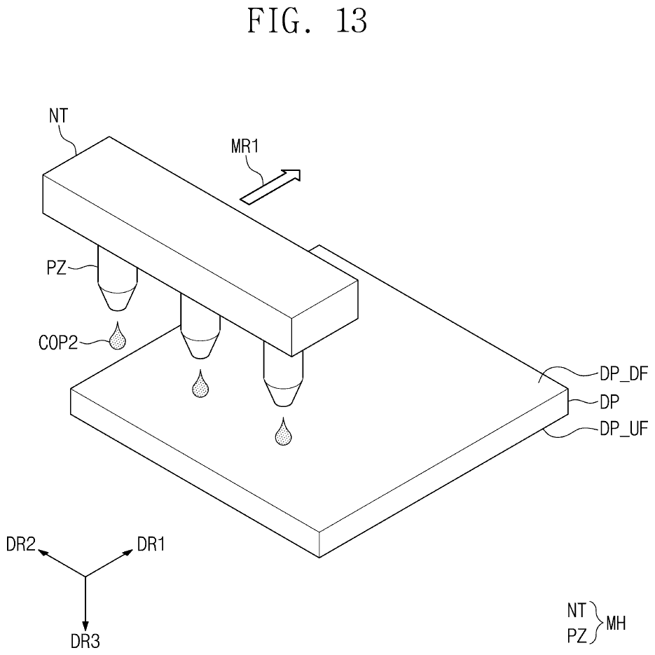

A display device in an embodiment of the inventive concept may be manufactured by a method of manufacturing a display device according to the inventive concept. FIGS. 12A and 12B are flowcharts showing an embodiment of the method of manufacturing the display device according to the inventive concept. FIGS. 13 to 17 schematically illustrate steps of manufacturing the display device according to the inventive concept. Hereinafter, in the descriptions of FIGS. 12A to 17, the contents overlapping those described with reference to FIGS. 1 to 11 will not be described again, and differences will be mainly described.

Referring to FIG. 12A, the method of manufacturing the display device in an embodiment of the inventive concept may include preparing a display panel (S100) and providing a lower coating layer on one surface of the display panel (S200). Referring to FIG. 12B, the providing of the lower coating layer (S200) may include forming a preliminary second coating layer (S210), curing the preliminary second coating layer to form a second coating layer (S220), forming a preliminary first coating layer (S230), and curing the preliminary first coating layer to form a first coating layer (S240).

Referring to FIG. 13, a second coating composition COP2 may be provided on one surface of the display panel DP. The display panel DP may include one surface DP_DF and an opposite surface DP_UF spaced apart from each other in the thickness direction DR3. In the thickness direction DR3, the one surface DP_DF of the display panel DP may be the lower surface of the display panel DP, which may be adjacent to the lower coating layer LC (refer to FIG. 3A). In the thickness direction DR3, the opposite surface DP_UF of the display panel DP may be the upper surface of the display panel DP. The opposite surface DP_UF of the display panel DP may be spaced apart from the lower coating layer LC (refer to FIG. 3A) with the one surface DP_DF of the display panel DP interposed therebetween.

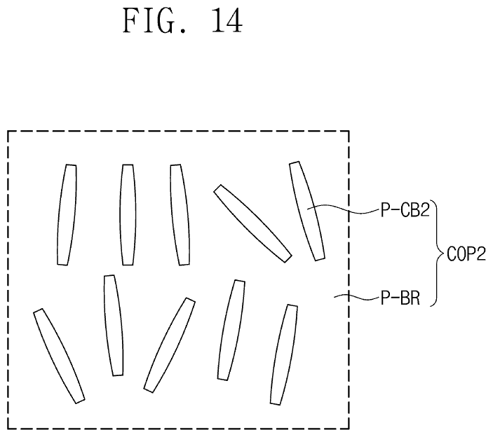

The second coating composition COP2 is a liquid composition and may be provided by a dispensing method. Accordingly, a coating layer may be formed in response to a member having various shapes. The second coating composition COP2 may be provided through a device MH. The device MH may include a controller NT and a plurality of providing units PZ. Each of the providing units PZ includes a nozzle, and the second coating composition COP2 may be provided through a plurality of nozzles. The controller NT may control the movement speed of the providing units PZ and the discharge amount of the composition. The device MH may move in a first movement direction MR1 on a plane, and the first movement direction MR1 may be parallel to the first direction DR1. When the device MH moves, the speed thereof may be about 100 millimeters per second (mm/s) or more. As the movement speed of the device is about 100 mm/s or more, it may be easy to provide the second coating composition COP2 including preliminary second sub-carbon fillers P-CB2 (refer to FIG. 14). The nozzle of the device that moves at a speed of less than about 100 mm/s is clogged, thus reducing manufacturing efficiency. In contrast, the method of manufacturing the display device in an embodiment of the inventive concept, which uses the device MH that moves at a speed of about 100 mm/s or more when the second coating composition COP2 is provided, may exhibit excellent manufacturing efficiency. The second coating composition COP2 may be provided from one side to an opposite side of the display panel DP along the first direction DR1 on a plane. The one side and an opposite side of the display panel DP may be spaced apart from each other in the first direction DR1.

FIG. 14 schematically illustrates the second coating composition COP2. The second coating composition COP2 may include a preliminary base resin P-BR and a plurality of preliminary second sub-carbon fillers P-CB2 dispersed in the preliminary base resin P-BR. The preliminary base resin P-BR may include at least one of an epoxy-based resin, an acrylic-based resin, a urethane-based resin, or a silicone-based resin. The preliminary second sub-carbon fillers P-CB2 may be carbon fibers.

With respect to the total weight of the second coating composition COP2, the weight of the preliminary second sub-carbon fillers P-CB2 may be about 50 wt % to about 90 wt %. The second coating composition COP2 including the preliminary second sub-carbon fillers P-CB2 that satisfy such a weight range may form the second coating layer LC-2 (refer to FIG. 5) having excellent stiffness and impact resistance.

Each of the preliminary second sub-carbon fillers P-CB2 may have a rod shape, and the length of the long side of each of the preliminary second sub-carbon fillers P-CB2 may be about 10 μm to about 200 μm. The length of the long side of each of the preliminary second sub-carbon fillers P-CB2 may be about 10 μm to about 50 μm or about 150 μm to about 200 μm. The second coating composition COP2 including the preliminary second sub-carbon fillers P-CB2 that satisfy such a length range may exhibit the characteristics of being easily discharged from the providing units PZ. The second coating composition COP2 may further include an additive or the like known in the art to improve the characteristics (heat dissipation, light-blocking, shielding, and shock absorption) of the lower coating layer LC (refer to FIG. 2).

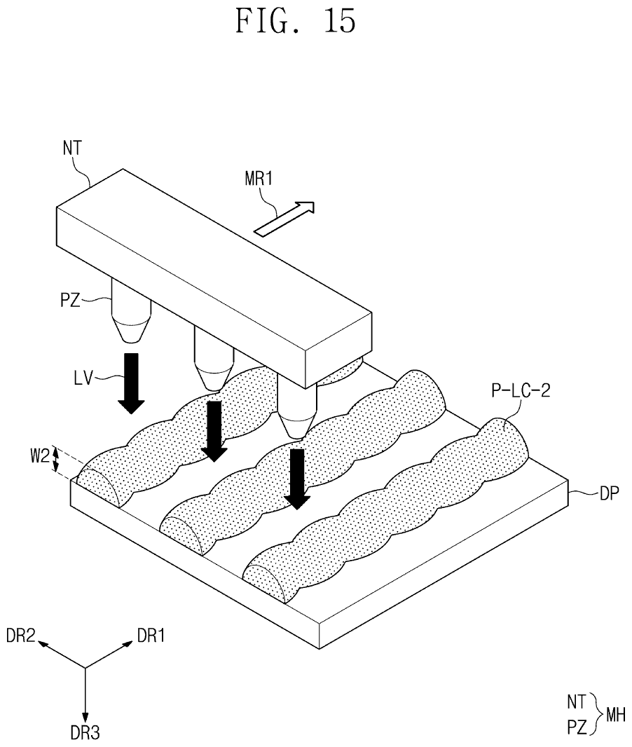

The second coating composition COP2 may be provided to form a preliminary second coating layer P-LC-2 illustrated in FIG. 15. A thickness W2 of the preliminary second coating layer P-LC-2 may be about 5 μm to about 30 μm. The preliminary second coating layer P-LC-2, which satisfies such a thickness W2 range, may form the second coating layer LC-2 (refer to FIG. 5) having excellent stiffness and impact resistance after curing.

Referring to FIG. 15, intense light (e.g., ultraviolet light LV) may be provided on the preliminary second coating layer P-LC-2. Ultraviolet light LV may be provided through the device MH. Each of the providing units PZ may include a light irradiator, and ultraviolet light LV may be provided through the light irradiator. The providing units PZ may include a nozzle and a light irradiator, and the device MH may be a device in which an applicator (i.e., nozzle) and a curing unit (i.e., light irradiator) are integrated with each other. The device MH may move in the first movement direction MR1 on a plane, and the first movement direction MR1 may be parallel to the first direction DR1. Ultraviolet light LV may be provided from one side to an opposite side of the display panel DP along the first direction DR1 on a plane. One side is a portion in which the preliminary second coating layer P-LC-2, formed by providing the second coating composition COP2 (refer to FIG. 13) earlier than an opposite side, is present, and an opposite side is a portion in which the preliminary second coating layer P-LC-2, formed by providing the second coating composition COP2 (refer to FIG. 13) later, is present. The preliminary second coating layer P-LC-2 formed by providing the second coating composition COP2 (refer to FIG. 13) earlier may be first irradiated with ultraviolet light LV. That is, the starting point at which the second coating composition COP2 is provided may be substantially the same as the starting point at which ultraviolet light LV is provided, and the ending point at which the second coating composition COP2 is provided may be substantially the same as the ending point at which ultraviolet light LV is provided. That is, ultraviolet light LV may be first provided to a portion at which the second coating composition COP2 is provided earlier.

As ultraviolet light LV is first provided to a portion to which the second coating composition COP2 is provided earlier, the preliminary second coating layer P-LC-2 may be cured up to the deep portion thereof in the thickness direction DR3. The deep portion of the preliminary second coating layer P-LC-2 may be spaced relatively far apart from the providing units PZ in the thickness direction DR3. When the starting point at which ultraviolet light LV is provided is the same as the ending point at which the second coating composition COP2 is provided, the preliminary second coating layer P-LC-2 may not be cured up to the deep portion thereof, thus reducing processability. Between the provision of the second coating composition COP2 (refer to FIG. 13) and the provision of ultraviolet light LV, the preliminary base resin P-BR (refer to FIG. 14) may spread on a plane. The liquid preliminary base resin P-BR may spread on a plane, and this may occur for a few seconds.

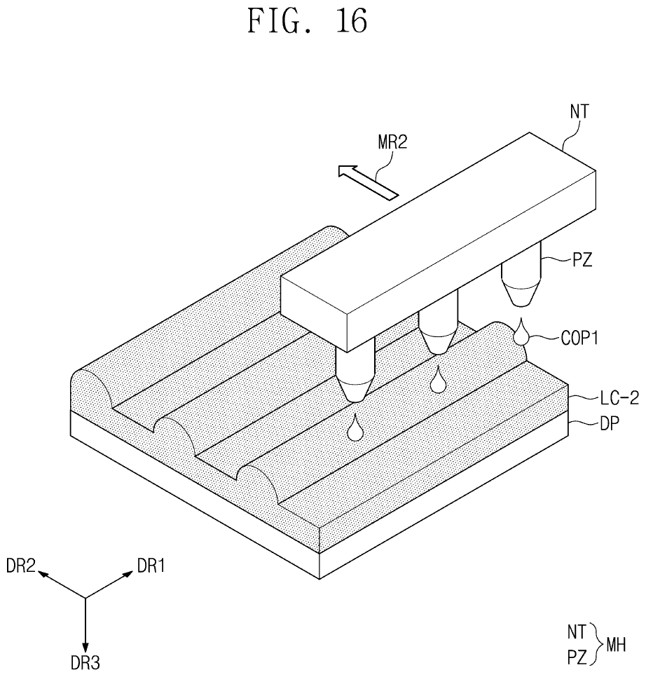

As the preliminary second coating layer P-LC-2 is cured by ultraviolet light LV, the second coating layer LC-2 illustrated in FIG. 16 may be formed. As the preliminary base resin P-BR (refer to FIG. 14) is cured, the base resin BR (refer to FIG. 7) may be formed. The second sub-carbon fillers CB2 (refer to FIG. 7) may be formed from the preliminary second sub-carbon fillers P-CB2.

Subsequently, for the formation of the first coating layer LC-1 (refer to FIGS. 5 and 6), the first coating composition COP1 may be provided as illustrated in FIG. 16. The first coating composition COP1 is a liquid composition and may be provided by a dispensing method. The first coating composition COP1 and the second coating composition COP2 may be substantially the same material as each other. The first coating composition COP1 may include the preliminary base resin P-BR (refer to FIG. 14) and the preliminary first sub-carbon fillers dispersed in the preliminary base resin P-BR. The preliminary first sub-carbon fillers are the same carbon fibers as the preliminary second sub-carbon fillers P-CB2 (refer to FIG. 14), and the same reference numeral is used for them.

With respect to the total weight of the first coating composition COP1, the weight of the first sub-carbon fillers P-CB2 (refer to FIG. 14) may be about 50 wt % to about 90 wt %. The first coating composition COP1 including the preliminary first sub-carbon fillers P-CB2 (refer to FIG. 14) that satisfy such a weight range may form the lower coating layer LC (refer to FIG. 5) having excellent stiffness and impact resistance. In addition, the first coating composition COP1 including the preliminary first sub-carbon fillers P-CB2 (refer to FIG. 14) that satisfy such a weight range may exhibit the characteristics of being easily provided by a dispensing method.

The first coating composition COP1 may be provided on the second surface LC2_DF (refer to FIG. 7) of the second coating layer LC-2. The first coating composition COP1 may be provided directly on the second surface LC2_DF (refer to FIG. 7) of the second coating layer LC-2. The first coating composition COP1 may be provided through the device MH.

When the first coating composition COP1 is provided, the device MH may move in a second movement direction MR2. The second movement direction MR2 may cross the first movement direction MR1 and may be parallel to the second direction DR2. The movement direction (i.e., the first movement direction MR1) of the device MH in the forming of the preliminary second coating layer P-LC-2 and the second coating layer LC-2 and the movement direction (i.e., the second movement direction MR2) of the device MH in the forming of the preliminary first coating layer P-LC-1 and the first coating layer LC-1 (refer to FIGS. 5 and 6) may cross each other. The method of forming the lower coating layer LC (refer to FIG. 5) by the device MH which moves in directions that cross each other like this may be similar to a weaving method. Accordingly, as described above, the lower coating layer LC (refer to FIG. 5) including the first and second sub-carbon fillers CB1 and CB2 (refer to FIG. 8) whose arrangement directions cross each other may be formed.

A typical coating composition including or consisting of a relatively large amount of carbon fillers dispersed in a base resin is not easy to cure by providing light. In an embodiment of the inventive concept, by providing the coating compositions COP1 and COP2 in multiple times in directions that cross each other, it is possible to provide them in a relatively thin thickness. Accordingly, the coating compositions COP1 and COP2 provided in a relatively thin thickness may exhibit the characteristics of being easily cured by light.

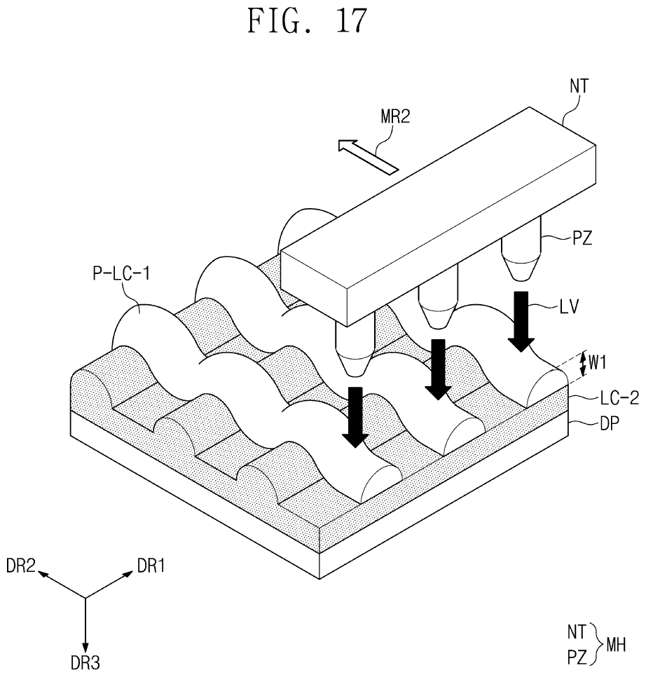

By providing the first coating composition COP1, the preliminary first coating layer P-LC-1 may be formed as illustrated in FIG. 17. A thickness W1 of the preliminary first coating layer P-LC-1 may be about 5 μm to about 30 μm. The preliminary first coating layer P-LC-1, which satisfies such a thickness W1 range, may form the lower coating layer LC (refer to FIG. 5) having excellent stiffness and impact resistance after curing.

Ultraviolet light LV may be provided through the device MH on the preliminary first coating layer P-LC-1. The starting point at which ultraviolet light LV is provided may be substantially the same as the starting point at which the first coating composition COP1 is provided, and the ending point at which ultraviolet light LV is provided may be substantially the same as the ending point at which the first coating composition COP1 is provided. Accordingly, the preliminary first coating layer may be cured up to the deep portion thereof in the thickness direction DR3, and the first coating layer LC-1 (refer to FIGS. 5 and 6) having excellent processability may be formed. In addition, the method of manufacturing the display device in an embodiment of the inventive concept may exhibit excellent manufacturing efficiency.

Unlike what is illustrated, the second coating layer LC-2 (refer to FIGS. 5 and 7) may be formed by providing the second coating composition COP2 (refer to FIG. 14) on a separate substrate and curing the second coating composition COP2 (refer to FIG. 14) provided on the substrate. The first coating layer LC-1 (refer to FIGS. 5 and 6) may be formed by providing the first coating composition COP1 (refer to FIG. 16) on a separate substrate and curing the first coating composition COP1 (refer to FIG. 16) provided on the substrate. The direction in which the first coating composition COP1 (refer to FIG. 16) is provided and the direction in which the second coating composition COP2 (refer to FIG. 14) is provided may cross each other. A separate substrate may be used without limitation as long as it is a member for the formation of the first and second coating layers LC-1 and LC-2. Hereafter, the second coating layer LC-2 (refer to FIGS. 5 and 7) and the first coating layer LC-1 (refer to FIGS. 5 and 6) may be sequentially provided on one surface DP_DF (refer to FIG. 13) of the display panel DP (refer to FIG. 13).

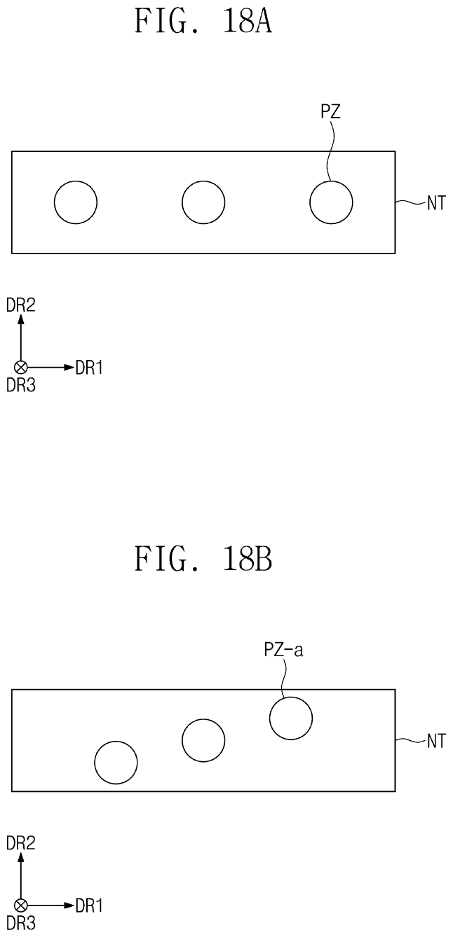

FIGS. 18A and 18B are plan views schematically illustrating the device MH and illustrate a view from above the device MH. Referring to FIG. 18A, the device MH may include the providing units PZ disposed side by side at regular intervals in the first direction DR1. Compared to the device MH illustrated in FIG. 18A, the device MH illustrated in FIG. 18B has a difference in that providing units PZ-a are not disposed side by side in the first direction DR1, but are disposed to form a diagonal line. When the lower coating layer LC (refer to FIG. 3A) is formed by the device MH illustrated in FIG. 18A, the lower coating layer LC may be formed as illustrated in FIG. 3A. That is, the lower coating layer LC (refer to FIG. 3A) including the convex portion CPO (refer to FIG. 3A) and the flat portion PPO (refer to FIG. 3A) may be formed.

The providing units PZ-a of FIG. 18B may be disposed in a narrower interval than that of the providing units PZ of FIG. 18A. The providing units PZ-a of FIG. 18B may be diagonally disposed and may be disposed at relatively narrow intervals. The compositions COP1 and COP2 discharged from the providing units disposed at relatively narrow intervals may be adjacent to each other. Accordingly, when the lower coating layer LC-X (refer to FIG. 3B) is formed by the device MH illustrated in FIG. 18B, the lower coating layer LC-X may be formed as illustrated in FIG. 3B. That is, the lower coating layer LC-X (refer to FIG. 3B), which includes the convex portion CPO (refer to FIG. 3B) and does not include the flat portion PPO (refer to FIG. 3A), may be formed.

The method of manufacturing the display device in an embodiment of the inventive concept may further include forming a preliminary fourth coating layer, curing the preliminary fourth coating layer to form a fourth coating layer, forming a preliminary third coating layer, and curing the preliminary third coating layer to form a third coating layer. The forming of the preliminary fourth coating layer, the fourth coating layer, the preliminary third coating layer, and the third coating layer may be performed prior to the forming of the preliminary second coating layer. That is, the fourth coating layer LC-4 (refer to FIG. 9) closest to the display panel DP (refer to FIG. 3A) may be formed the very first, and the first coating layer LC-1 (refer to FIG. 9) furthest away from the display panel DP (refer to FIG. 3A) may be formed the very last.

The method of forming the fourth coating layer LC-4 (refer to FIG. 9) may be performed in the same method as the forming of the second coating layer LC-2 (refer to FIG. 9), except for the position at which the fourth coating composition is provided. The preliminary fourth coating layer may be formed by providing the fourth coating composition, and the fourth coating layer LC-4 (refer to FIG. 9) may be formed by curing the preliminary fourth coating layer. The fourth coating composition may be provided on one surface DP_DF of the display panel DP (refer to FIG. 13). The fourth coating composition may be provided directly on one side of the display panel DP (refer to FIG. 13). The fourth coating composition is a liquid composition and may be provided by a dispensing method.

The fourth coating composition includes the same material as that of the second coating composition COP2 (refer to FIG. 14), and the same reference numeral is used for them. The fourth coating composition may include a preliminary base resin P-BR (refer to FIG. 14) and preliminary fourth sub-carbon fillers dispersed in the preliminary base resin P-BR (refer to FIG. 14). The preliminary fourth sub-carbon fillers are the same carbon fibers as the preliminary second sub-carbon fillers P-CB2 (refer to FIG. 14), and the same reference numeral is used for them.

The movement direction of the device MH (refer to FIG. 13) for providing the fourth coating composition COP2 (refer to FIG. 14) may be the same as the movement direction (i.e., the first movement direction MR1) of the device MH (refer to FIG. 13) for providing the second coating composition COP2 (refer to FIG. 13). The fourth coating layer LC-4 (refer to FIG. 9) may be formed by providing ultraviolet light LV (refer to FIG. 15) to the preliminary fourth coating layer formed by providing the fourth coating composition COP2 (refer to FIG. 14). The movement direction of the device MH (refer to FIG. 15) for providing ultraviolet light LV (refer to FIG. 15) to the preliminary fourth coating layer may be the same as the movement direction (i.e., the first movement direction MR1) of the device MH (refer to FIG. 15) for providing ultraviolet light LV (refer to FIG. 15) to the preliminary second coating layer P-LC-2 (refer to FIG. 15).

The method of forming the third coating layer LC-3 (refer to FIG. 9) may be performed in the same way as the method of forming the first coating layer LC-1 (refer to FIG. 9), except for the position at which the third coating composition is provided. The preliminary third coating layer may be formed by providing the third coating composition, and the third coating layer LC-3 (refer to FIG. 9) may be formed by curing the preliminary third coating layer. The third coating composition may be provided on the fourth surface LC4_DF (refer to FIG. 11) of the fourth coating layer LC-4 (refer to FIG. 11). The third coating composition may be provided directly on the fourth surface LC4_DF (refer to FIG. 11) of the fourth coating layer LC-4 (refer to FIG. 11). The third coating composition is a liquid composition and may be provided by a dispensing method.

The third coating composition may include the same material as that of the first coating composition COP1 (refer to FIG. 16). The third coating composition includes the same material as that of the second coating composition COP2 (refer to FIG. 14), and the same reference numeral is used for them. The third coating composition may include a preliminary base resin P-BR (refer to FIG. 14) and preliminary third sub-carbon fillers dispersed in the preliminary base resin P-BR (refer to FIG. 14). The preliminary third sub-carbon fillers are the same carbon fibers as the preliminary second sub-carbon fillers P-CB2 (refer to FIG. 14), and the same reference numeral is used for them.

The movement direction of the device MH (refer to FIG. 16) for providing the third coating composition may be the same as the movement direction (i.e., the second movement direction MR2) of the device MH (refer to FIG. 16) for providing the first coating composition COP1 (refer to FIG. 16). The third coating layer LC-3 (refer to FIG. 9) may be formed by providing ultraviolet light LV (refer to FIG. 17) to the preliminary third coating layer formed by providing the third coating composition. The movement direction of the device MH (refer to FIG. 17) for providing ultraviolet light LV (refer to FIG. 17) to the preliminary third coating layer may be the same as the movement direction (i.e., the second movement direction MR2) of the device MH (refer to FIG. 17) for providing ultraviolet light LV (refer to FIG. 17) to the preliminary first coating layer P-LC-1 (refer to FIG. 17).

It has been described above that the lower coating layer LC-a (refer to FIG. 9) including the first to fourth coating layer LC-1, LC-2, LC-3, and LC-4 (refer to FIG. 9) is formed by providing the coating composition four times, but the embodiment of the inventive concept is not limited thereto. In an embodiment, the lower coating layer may be formed by providing the coating composition five times or more in directions that cross each other, for example.

The method of manufacturing the display device in an embodiment of the inventive concept may include providing a coating composition including carbon fillers to form a lower coating layer. The coating composition is a liquid composition and may be provided by a dispensing method. Accordingly, the method of manufacturing the display device in an embodiment of the inventive concept may exhibit excellent manufacturing efficiency.

The display device in an embodiment of the inventive concept may be manufactured by the method of manufacturing the display device according to the inventive concept. The display device in an embodiment of the inventive concept may include a lower coating layer disposed below the display panel. The lower coating layer is a functional layer that performs multiple functions such as heat dissipation, light-blocking, shielding, and shock absorption and may include carbon fillers disposed in arrangement directions that cross each other. Accordingly, the display device including the lower coating layer may have a reduced thickness and exhibit excellent reliability.

By including a lower coating layer composed of carbon fillers disposed in arrangement directions that cross each other, the display device in an embodiment of the inventive may have a reduced thickness and exhibit excellent reliability.

The method of manufacturing the display device in an embodiment of the inventive concept may exhibit excellent manufacturing efficiency as the method includes providing a coating composition including carbon fillers to form a lower coating layer.

Although the above has been described with reference to preferred embodiments of the inventive concept, those skilled in the art or those of ordinary skill in the art will understand that various modifications and changes may be made to the inventive concept within the scope that does not depart from the spirit and technical field of the inventive concept described in the claims to be described later.

Accordingly, the technical scope of the inventive concept should not be limited to the content described in the detailed description of the specification, but should be determined by the claims described hereinafter.

What is claimed is:

1. An electronic device comprising:
a lower coating layer comprising:
a base resin;
a plurality of carbon fillers dispersed in the base resin, the plurality of carbon fillers comprising:
a plurality of first sub-carbon fillers disposed in a first arrangement direction; and
a plurality of second sub-carbon fillers disposed in a second arrangement direction crossing the first arrangement direction;
a lower surface; and
an upper surface opposite to the lower surface; and
a display panel disposed on the lower coating layer,
wherein:
the lower surface of the lower coating layer includes a convex portion convex in a direction away from the display panel and is spaced apart from the display panel with the upper surface of the lower coating layer interposed therebetween.

2. The electronic device of claim 1, wherein each of the plurality of carbon fillers is a carbon fiber.

3. The electronic device of claim 1, wherein the lower coating layer comprises:
a first coating layer comprising the base resin and the plurality of first sub-carbon fillers dispersed in the base resin; and
a second coating layer comprising the base resin and the plurality of second sub-carbon fillers dispersed in the base resin and disposed between the first coating layer and the display panel.

4. The electronic device of claim 3, wherein the lower surface of the lower coating layer is the lower surface of the first coating layer.

5. The electronic device of claim 1, wherein:
the lower surface of the lower coating layer further comprises a flat portion adjacent to the convex portion; and
the plurality of first sub-carbon fillers is disposed in the convex portion and are not disposed in the flat portion.

6. The electronic device of claim 3, wherein the plurality of carbon fillers further comprises:
a plurality of third sub-carbon fillers disposed in the first arrangement direction; and
a plurality of fourth sub-carbon fillers disposed in the second arrangement direction,
wherein the lower coating layer further comprises:
a third coating layer comprising the base resin and the plurality of third sub-carbon fillers dispersed in the base resin and disposed between the second coating layer and the display panel; and
a fourth coating layer comprising the base resin and the plurality of fourth sub-carbon fillers dispersed in the base resin and disposed between the third coating layer and the display panel.

7. The electronic device of claim 1, wherein each of the plurality of carbon fillers has a rod shape, and a length of a long side of the rod shape is about 10 micrometers to about 200 micrometers.

8. The electronic device of claim 1, wherein the base resin is a photocurable resin.

9. The electronic device of claim 1, wherein the base resin comprises at least one of an epoxy-based resin, an acrylic-based resin, a urethane-based resin, or a silicone-based resin.

10. The electronic device of claim 1, wherein, based on a total weight, which is 100 wt %, of the lower coating layer, a weight of the plurality of carbon fillers is about 50 wt % to about 90 wt %.

11. The electronic device of claim 1, wherein the upper surface of the lower coating layer is flat.

12. A method for manufacturing a display device, the method comprising:
preparing a display panel; and
providing a lower coating layer comprising a base resin and a plurality of carbon fillers dispersed in the base resin on a surface of the display panel,
wherein the plurality of carbon fillers comprises:
a plurality of first sub-carbon fillers disposed in a first arrangement direction; and
a plurality of second sub-carbon fillers disposed in a second arrangement direction crossing the first arrangement direction,
wherein the providing the lower coating layer comprises:
providing a second coating composition comprising a preliminary base resin and a plurality of preliminary second sub-carbon fillers dispersed in the preliminary base resin in a first direction and forming a preliminary second coating layer;
curing the preliminary second coating layer and forming a second coating layer comprising the base resin and the second sub-carbon fillers dispersed in the base resin;
on a surface of the second coating layer, providing a first coating composition comprising the preliminary base resin and a plurality of preliminary first sub-carbon fillers dispersed in the preliminary base resin in a second direction crossing the first direction and forming a preliminary first coating layer; and
curing the preliminary first coating layer and forming a first coating layer comprising the base resin and the plurality of first sub-carbon fillers dispersed in the base resin.

13. The method of claim 12, wherein the plurality of carbon fillers further comprises:
a plurality of third sub-carbon fillers disposed in the first arrangement direction; and
a plurality of fourth sub-carbon fillers disposed in the second arrangement direction,
wherein the forming the lower coating layer further comprises:
prior to the forming the preliminary second coating layer, providing a fourth coating composition comprising the preliminary base resin and a plurality of preliminary fourth sub-carbon fillers dispersed in the preliminary base resin on the surface of the display panel in the second direction and forming a preliminary fourth coating layer;
curing the preliminary fourth coating layer and forming a fourth coating layer comprising the base resin and the plurality of fourth sub-carbon fillers dispersed in the base resin;
on a surface of the fourth coating layer, providing a third coating composition comprising the preliminary base resin and a plurality of preliminary third sub-carbon fillers dispersed in the preliminary base resin in the first direction and forming a preliminary third coating layer; and
curing the preliminary third coating layer and forming a third coating layer comprising the base resin and the plurality of third sub-carbon fillers dispersed in the base resin.

14. The method of claim 12, wherein the first coating composition and the second coating composition are provided by a dispensing method.

15. The method of claim 12, wherein each of the plurality of carbon fillers is a carbon fiber.

16. The method of claim 12, wherein:
each of the plurality of carbon fillers has a rod shape; and
a length of a long side of the rod shape is about 10 micrometers to about 200 micrometers.

17. The method of claim 12, wherein a thickness of each of the preliminary first coating layer and the preliminary second coating layer is about 5 micrometers to about 30 micrometers.

18. The method of claim 12, wherein:
based on a total weight of the first coating composition, a weight of the plurality of preliminary first sub-carbon fillers is about 50 wt % to about 90 wt %; and
based a total weight of the second coating composition, a weight of the plurality of preliminary second sub-carbon fillers is about 50 wt % to about 90 wt %.

19. The method of claim 12, wherein ultraviolet light is provided in the curing the preliminary first coating layer and the curing the preliminary second coating layer.

20. The method of claim 12, wherein the preliminary base resin comprises at least one of an epoxy-based resin, an acrylic-based resin, a urethane-based resin, or a silicone-based resin.
